(19) United States
(12) Patent Application Publication
(10) Pub. No.: US 2026/0351702 A1
(43) Pub. Date: Nov. 5, 2026

(54) Test Fixture for Battery Cells

(71) Applicant: Supernal, LLC, Irvine, CA (US)

(72) Inventors: Joseph Andrew Bodo, Irvine, CA (US); Tanner Hanson, Irvine, CA (US)

(21) Appl. No.: 19/488,263

(22) PCT Filed: Jun. 14, 2024
(86) PCT No.: PCT/US2024/034157

§ 371 Date: Nov. 26, 2025

Related U.S. Application Data
(60) Provisional application No. 63/521,622, filed on Jun. 16, 2023.

(51) Int. Cl. H01M 10/48; H01M 10/42; H01M 10/6572

(52) U.S. Cl. CPC H01M 10/486; H01M 10/4285; H01M 10/6572

(57) ABSTRACT

A testing apparatus includes a base, a mounting frame including a plurality of supports coupled to the base, a plurality of temperature control assemblies, a positive contact fixture configured to contact a positive electrode of a battery, a negative contact fixture configured to contact a negative electrode of the battery, and a process controller. Each temperature control assembly includes a thermal interface material (TIM) layer disposed on the surface of a metal fixture configured to align with the shape and size of a battery; a thermoelectric junction disposed between the metal fixture and a heat sink, where each heat sink is coupled to a ducted fan assembly; and a relay switch coupled to each thermoelectric junction. The process controller is coupled to the relay switches and configured to control the relay switches to regulate the temperature of the thermoelectric junction plates.

### CROSS REFERENCE TO RELATED APPLICATIONS

The present application claims priority to U.S. Provisional Application No. 63/521,622, filed on Jun. 16, 2023, the entire contents of which are herein incorporated by reference as if fully set forth in this description.

### BACKGROUND

Batteries are used in many applications including consumer electronics, electric vehicles, robots, aircraft, and power-grid storage. A battery goes through many cycles of charging and discharging throughout its life.

An example battery includes several battery modules, each battery module having a respective plurality of battery cells. The battery may heat up during charging, and particularly during fast charging rates (e.g., high coulomb rates). Further, during periods of high demand on the battery, the battery may heat up substantially.

High temperatures reduce the lifespan of the battery, and may lead to an increase in the risk of a thermal runaway event (e.g., an event where a strong exothermic chain reaction occurs within a battery cell, and the battery cell enters an uncontrollable, self-heating state that could result in ejection of gas, shrapnel, and/or particulates). It may thus be desirable to configure the battery with thermal protection features.

Additionally, battery cells heat up during high-load testing, leading to invalid test results. In commonly known applications, battery cell testing fixtures are placed inside temperature-controlled chambers which utilize liquid coolant techniques to attempt to reduce the temperature of the battery cells during high-load testing. However, these applications and methods do not provide precise control over the cooling process. Therefore, there exists a need for systems and methods for accurately controlling the temperature of a battery cell during high-load testing.

Further, it may be desirable to accurately and adequately perform tests on the battery to determine the effects of high temperatures on the lifespan and energy performance of the battery. It may also be desirable to perform tests in an environment that is similar to the application environments and conditions of the battery. In some commonly known applications, battery cells are positioned between two spring loaded fixtures in order to test the battery cells. However, any contact with the battery cells can lead to heat generation from contact resistance. In some use environments of battery cells, the battery cells are only contacted on one side. Therefore, there exists a need for a testing apparatus that only contacts the battery cells on one side in order to prevent unrealistic heat generation from unrealistic contact resistance.

It is with respect to these and other considerations that the disclosure made herein is presented.

### SUMMARY

The present disclosure describes implementations that relate to a test fixture for a battery and method of assembly thereof.

In a first example embodiment, a testing apparatus includes a base; a mounting frame including a plurality of supports coupled to the base; a plurality of temperature control assemblies. Each temperature control assembly includes a respective thermal interface material (TIM) layer disposed on the surface of a respective metal fixture configured to align with the shape and size of a battery; a respective thermoelectric junction disposed between the respective metal fixture and a respective heat sink, wherein each respective heat sink is coupled to a respective ducted fan assembly; and a respective relay switch coupled to each respective thermoelectric junction. The testing apparatus also includes a positive contact fixture configured to contact a positive electrode of the battery; a negative contact fixture configured to contact a negative electrode of the battery; and a process controller coupled to the relay switches, the process controller configured to control the relay switches to regulate the temperature of the thermoelectric junction plates.

In some embodiments, each of the plurality of temperature control assemblies further includes a temperature sensor coupled to the respective metal fixture.

In some embodiments, the temperature sensor is further coupled to the process controller such that the process controller controls the relay switches based on inputs received from the temperature sensor.

In some embodiments, the thermoelectric junction is a Peltier junction.

In some embodiments, in response to a temperature of the battery being above a predetermined temperature set point, the process controller reverses a direction of current flow to the Peltier junction.

In some embodiments, the thermoelectric junction is controllable to provide heat to, or remove heat from, the battery.

In some embodiments, the battery has a first end and a second end opposite the first end, and where the negative contact fixture and the positive contact fixture each contacts the battery proximal to the first end.

In some embodiments, the positive contact fixture includes a first probe, a second probe, and a third probe, and wherein the first, second, and third probes each contacts a same surface of the positive electrode of the battery.

In some embodiments, the positive contact fixture includes a single probe.

In some embodiments, the negative contact fixture defines an arcuate profile sized and shaped to engage with a lip of the battery.

In some embodiments, the size and shape of the arcuate profile is less than an arcuate profile defined by the lip of the battery such that the negative contact fixture forms an interference fit with the lip.

In some embodiments, the negative contact fixture includes an elastically deformable material that elastically deforms to engage with a lip of the battery.

In some embodiments, the negative contact fixture includes a spring, where biasing the spring in a first direction contacts the negative contact fixture with the battery and biasing the spring in a second direction removes contact between the negative test fixture and the battery.

In some embodiments, the negative contact fixture is coupled to a hinge such that (i) rotation of the negative contact fixture about the hinge in a first directions contacts the battery and (ii) rotation of the negative contact fixture about the hinge in a second direction removes contact with the battery.

In some embodiments, the process controller is a pulse width modulation (PWM) controller, and the PWM controller varies a non-zero amount of electrical power supplied to the thermoelectric junctions.

In some embodiments, in response to a temperature of the battery being above a predetermined temperature set point, the process controller increases a fan speed of the respective ducted fan assembly.

In some embodiments, where the battery is a cylindrical cell having a top, a bottom opposite the top, and a cylindrical body disposed between the top and the bottom, the plurality of temperature control assemblies further include: a first temperature control assembly engaged with the bottom; a second temperature control assembly engaged with a first longitudinal half of the body; and a third temperature control assembly engaged with a second longitudinal half of the body, such that the bottom and the body of the battery are housed within the plurality of temperature control assemblies.

In a second example embodiment, a testing system includes: a plurality of testing apparatuses, where each testing apparatus includes: a battery; a base; a mounting frame including a plurality of supports coupled to the base; and a plurality of temperature control assemblies. Each temperature control assembly includes a respective thermal interface material (TIM) layer disposed on the surface of a respective metal fixture configured to align with the shape and size of the battery; a respective thermoelectric junction disposed between the respective metal fixture and a respective heat sink, where each respective heat sink is coupled to a respective ducted fan assembly; and a respective relay switch coupled to each respective thermoelectric junction. Each testing apparatus also includes a positive contact fixture configured to contact a positive electrode of the battery; a negative contact fixture configured to contact a negative electrode of the battery; and a process controller coupled to the relay switches, the process controller configured to control the relay switches to regulate the temperature of the thermoelectric junction plates. The testing system also includes a computing device coupled to the plurality of testing apparatuses, where the computing device receives testing information from each of the plurality of testing apparatuses.

In some embodiments, at least one of the thermoelectric junctions is a Peltier junction.

In a third example embodiment, a method for testing a battery using a testing apparatus including a plurality of temperature control assemblies each including a thermal interface material disposed on a metal fixture, a heat sink coupled to a ducted fan and the metal fixture, and a thermoelectric junction disposed between the metal fixture and the heat sink is provided. The method includes placing the battery into the testing apparatus, where the battery contacts a surface of the thermal interface material of each of the plurality of temperature control assemblies. The method also includes positioning a positive contact of the testing apparatus in contact with a positive electrode of the battery. The method further includes positioning a negative contact of the testing apparatus in contact with a negative electrode of the battery located proximal to the positive electrode, where the negative contact elastically deforms to a surface of the battery. The method additionally includes controlling, using a process controller coupled to the thermoelectric junction, a temperature of the battery by controlling current flow through the thermoelectric junction.

In a fourth example embodiment, the present disclosure describes a testing apparatus including a base and a mounting assembly, including a plurality of supports, coupled to the base. The testing apparatus also includes a plurality of temperature control assemblies, each temperature control assembly including a respective thermal interface material (TIM) layer disposed on the surface of a respective metal fixture configured to align with the shape and size of a battery. In some embodiments the metal fixture may be made of materials with high thermal conductivity, such as copper or aluminum. The testing apparatus additionally includes a positive contact fixture configured to contact the positive electrode of a battery and a negative contact fixture configured to contact the negative electrode of the battery. Each temperature control assembly further includes a thermoelectric junction plate (e.g., a Peltier junction) disposed between the respective metal fixtures and a respective heat sink. Each respective heat sink is further coupled to a respective ducted fan assembly configured to cool the fins of the respective heat sinks. The testing apparatus may further include a plurality of power supplies coupled to the ducted fan assemblies, the power supplies configured to power the ducted fan assemblies. The thermoelectric junction plates may be coupled to relay switches, the relay switches configured to provide electrical current to the thermoelectric junction plates. Further, the testing apparatus may include a process controller coupled to the relay switches, the process controller configured to control the relay switches to regulate the temperature of the thermoelectric junction plates.

The foregoing summary is illustrative only and is not intended to be in any way limiting. In addition to the illustrative aspects, implementations, and features described above, further aspects, implementations, and features will become apparent by reference to the drawings and the following detailed description.

### BRIEF DESCRIPTION OF THE FIGURES

FIG. 1A illustrates a perspective view of a testing apparatus, according to exemplary embodiments of the present invention.

FIG. 1B illustrates an exploded perspective view of the testing apparatus of FIG. 1A.

FIG. 2A illustrates a perspective view of a lower temperature control assembly, according to exemplary embodiments of the present invention.

FIG. 2B illustrates a perspective view of a rear temperature control assembly, according to exemplary embodiments of the present invention.

FIG. 2C illustrates a perspective view of an upper temperature control assembly, according to exemplary embodiments of the present invention.

FIG. 3 illustrates a perspective view of a negative contact fixture, according to exemplary embodiments of the present invention.

FIG. 4 illustrates a perspective view of a positive contact fixture, according to exemplary embodiments of the present invention.

FIG. 5 illustrates a perspective view of a use case of a testing apparatus, according to exemplary embodiments of the present invention.

FIG. 6A illustrates a perspective view of a testing apparatus, according to exemplary embodiments of the present invention.

FIG. 6B illustrates a top cross-sectional view of the testing apparatus of FIG. 6A having a battery cell installed, according to exemplary embodiments of the present invention.

FIG. 6C illustrates a side cross-sectional view of the testing apparatus of FIG. 6A having a battery cell installed, according to exemplary embodiments of the present invention.

FIG. 6D illustrates a side cross-sectional view of the testing apparatus of FIG. 6A having a battery cell installed, according to exemplary embodiments of the present invention.

FIG. 7A illustrates a perspective view of a lower temperature control assembly, according to exemplary embodiments of the present invention.

FIG. 7B illustrates a cross-sectional view of the lower temperature control assembly of FIG. 7A, according to exemplary embodiments of the present invention.

FIG. 8A illustrates a perspective view of an upper temperature control assembly, according to exemplary embodiments of the present invention.

FIG. 8B illustrates a cross-sectional view of the upper temperature control assembly of FIG. 8A, according to exemplary embodiments of the present invention.

FIG. 9A illustrates a perspective view of a rear temperature control assembly, according to exemplary embodiments of the present invention.

FIG. 9B illustrates a cross-sectional view of the rear temperature control assembly of FIG. 9A, according to exemplary embodiments of the present invention

FIG. 10A illustrates a perspective view of a negative contact fixture, according to exemplary embodiments of the present invention.

FIG. 10B illustrates another perspective view of the negative contact fixture, according to exemplary embodiments of the present invention.

FIG. 11A illustrates a perspective view of a portion of the negative contact fixture of FIGS. 10A and 10B, according to exemplary embodiments of the present invention.

FIG. 11B illustrates another perspective view of the portion of the negative contact fixture of FIG. 11A, according to exemplary embodiments of the present invention.

FIG. 12 illustrates a perspective view of a positive contact fixture, according to exemplary embodiments of the present invention.

FIG. 13 illustrates a perspective view of a base of the testing apparatus of FIG. 6A, according to exemplary embodiments of the present invention.

FIG. 14A illustrates a perspective view of a lower ducted fan assembly, according to exemplary embodiments of the present invention.

FIG. 14B illustrates a perspective view of an upper ducted fan assembly, according to exemplary embodiments of the present invention.

FIG. 14C illustrates a perspective view of a rear ducted fan assembly, according to exemplary embodiments of the present invention.

FIG. 15 illustrates a simplified box diagram of various components coupled to the testing apparatus, according to exemplary embodiments of the present invention.

### DETAILED DESCRIPTION

Disclosed herein are systems and assemblies for testing cylindrical battery cells. The disclosed systems, assemblies, and methods are applicable to any type of battery (e.g., lithium-ion batteries, batteries having silicon-alloy/graphite blend negative electrode combined with a nickel rich lithium nickel manganese cobalt oxide as positive electrode, lithium metal batteries, etc.).

The disclosed systems, assemblies, and methods may be utilized to test batteries that are used in any application or environment, including but not limited to a ground vehicle (i.e., an automobile), a sea vehicle (such as a boat), or a flying craft (such as an aerial, floating, soaring, hovering, airborne, aeronautical aircraft, airplane, plane, spacecraft, a helicopter, an airship, or an unmanned aerial vehicle, a vertical take-off and landing (VTOL) craft, or a drone). The disclosed embodiments of the present invention may be used to test under similar conditions to any of these environments and applications. Specifically, the disclosed embodiments of the present invention may test the batteries under the same temperature and load conditions as to any of these environments and applications.

Embodiments described herein may include a testing apparatus configured to fix a battery cell in place while maintaining temperature conditions of the battery cell. Beneficially, these embodiments may include using a curved metal component (e.g., copper) to contact the lip of a cylindrical battery cell to minimize contact resistance and heat generation during load testing of the battery cell. The curved metal component may be configured to plastically deform to accommodate the shape and size of the battery cell. Further, these embodiments may include probing only the top surface of the battery cell, minimizing contact resistance and heat generation during load testing of the battery cell. Additionally, the embodiments described herein may include using Peltier junctions to control the temperature of the testing apparatus which encapsulates the battery cell.

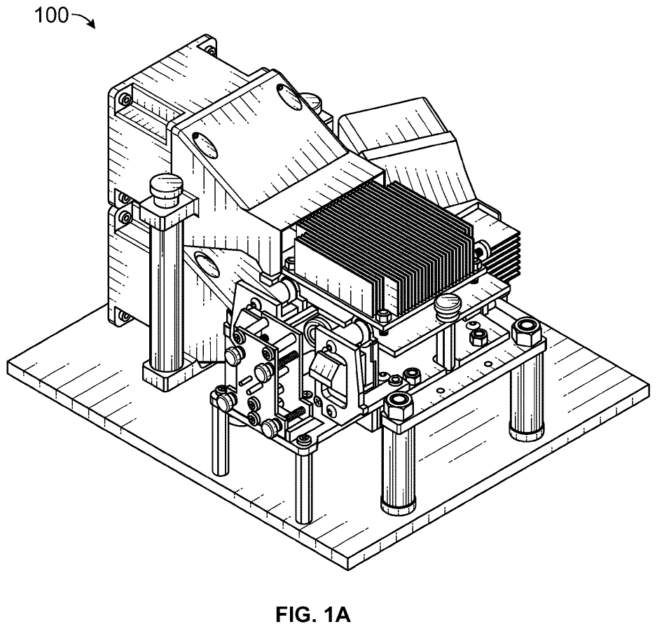

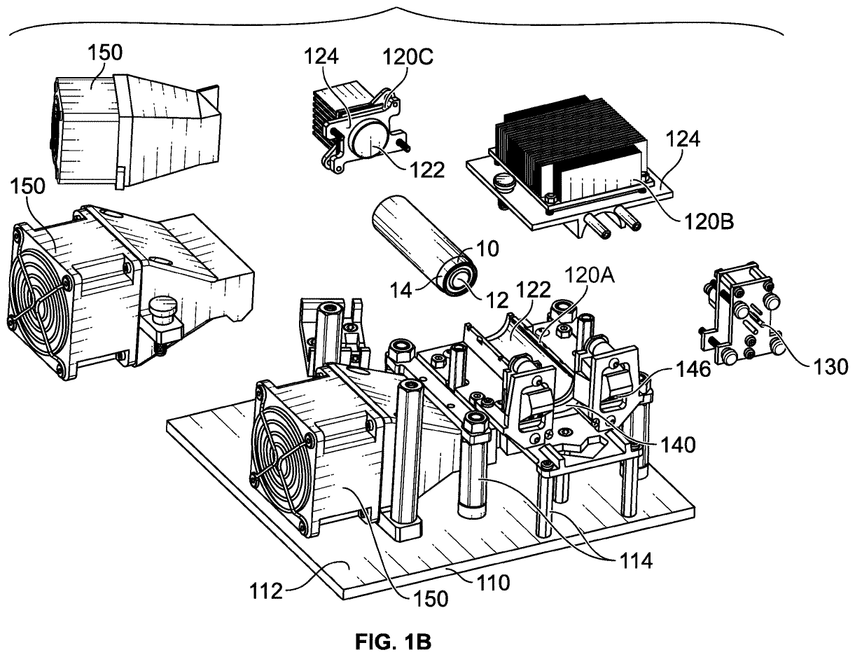

As illustrated by FIGS. 1A and 1B, the present disclosure describes a testing apparatus 100 which includes a base 110 and a mounting assembly 112, including a plurality of supports 114, coupled to the base 110. The testing apparatus also includes a plurality of temperature control assemblies 120A-120C, each temperature control assembly 120A-120C including a respective thermal interface material (TIM) layer 122 disposed on the surface of a respective metal fixture 124 configured to align with the shape and size of a battery 10. In some embodiments the metal fixture 124 may be made of materials with high thermal conductivity, such as copper or aluminum. The testing apparatus 100 additionally includes a positive contact fixture 130 configured to contact the positive electrode 12 of a battery cell 10 and a negative contact fixture 140 configured to contact the negative electrode 14 of the battery cell 10.

Each temperature control assembly 120A-120C further includes a thermoelectric junction plate 126 (e.g., a Peltier junction) disposed between the respective metal fixtures 124 and a respective heat sink 128. Each respective heat sink 128 is further coupled to a respective ducted fan assembly 150 configured to cool the fins of the respective heat sinks. The testing apparatus 100 may further include a plurality of power supplies coupled to the ducted fan assemblies 150, the power supplies configured to power the ducted fan assemblies 150. The thermoelectric junction plates 126 may be coupled to relay switches, the relay switches configured to provide electrical current to the thermoelectric junction plates 126. Further, the testing apparatus 100 may include a process controller coupled to the relay switches, the process controller configured to control the relay switches to regulate the temperature of the thermoelectric junction plates 126.

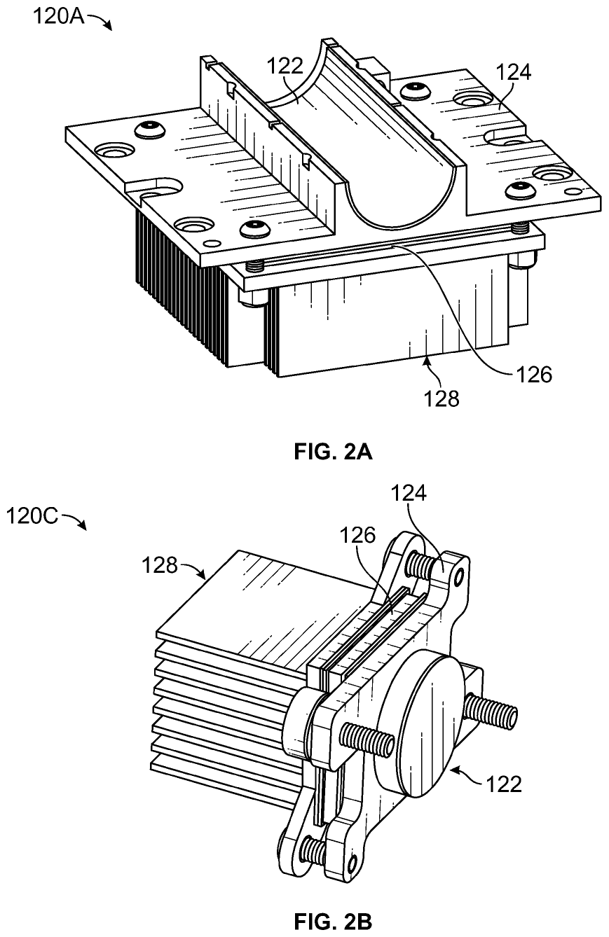

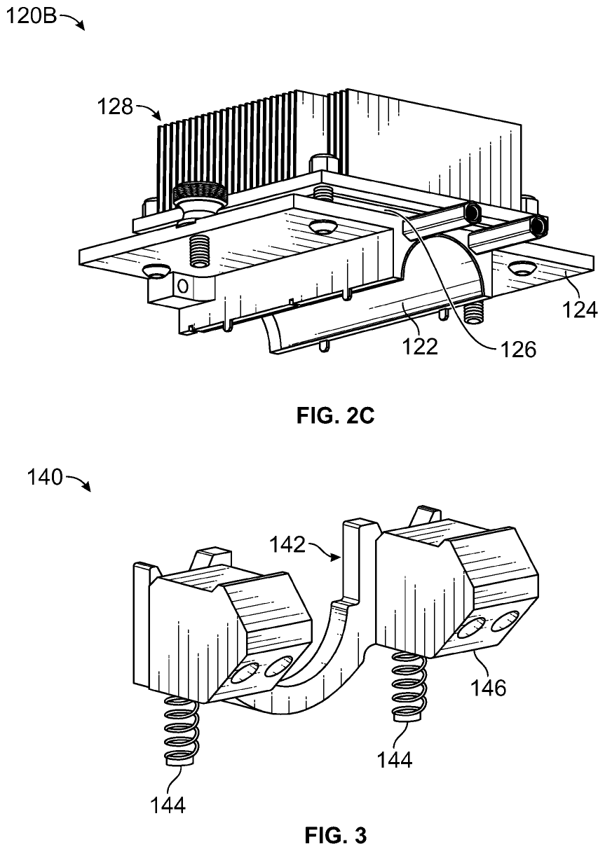

In some embodiments, the plurality of temperature control assemblies 120A-120C may include a lower temperature control assembly 120A (illustrated in FIG. 2A), a rear temperature control assembly 120C (illustrated in FIG. 2B), and an upper temperature control assembly 120B (illustrated in FIG. 2C). The lower temperature control assembly 120A may be coupled to the base 110 and/or mounting assembly 112. The upper temperature control assembly 120B may be configured to couple to the mounting assembly 112 and/or the lower temperature control assembly 120A. The rear temperature control assembly 120C may be configured to couple to the upper temperature control assembly 120B and/or the mounting assembly 112. In such embodiments, the plurality of temperature control assemblies 120A-120C are configured such that a battery cell 10 may be placed on the lower temperature control assembly 120A, and when the upper temperature control assembly 120B and the rear temperature control assembly 120C are coupled to the respective assemblies, the battery cell 10 is fixed between the plurality of temperature control assemblies 120A-120C while a front portion of the battery cell 10 is exposed. The front portion of the battery cell 10 includes a negative electrode 14 configured to contact the negative contact fixture 140 and a positive electrode 12 configured to contact the positive contact fixture 130.

As illustrated in FIG. 3, in some embodiments, the negative contact fixture 140 includes a copper plate 142 shaped similar to a crimped case of a battery cell 10, a plurality of springs 144 coupled to the copper plate 142, and at least one wire terminal 146 coupled to the copper plate 142. In such embodiments, the negative contact fixture 140 is configured to elastically deform to fit the battery cell 10.

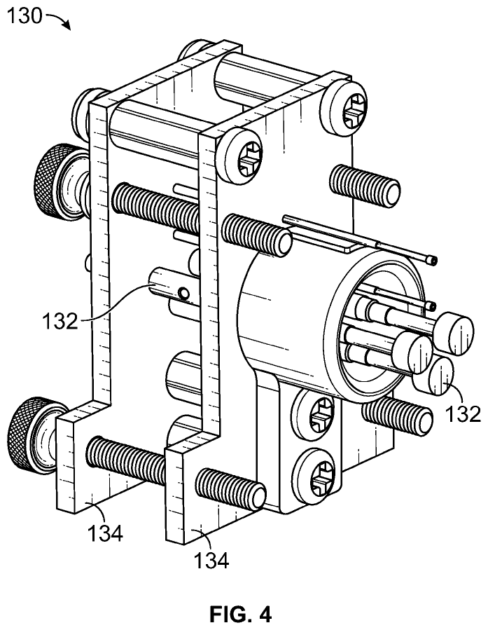

As illustrated in FIG. 4, in some embodiments, the positive contact fixture 130 includes at least one metal pin 132 (e.g., a spring-loaded pogo pin) positioned to connect with the positive electrode 12 of the battery cell 10 and configured to draw power from the battery cell 10. In some embodiments, metal pins 132 of the positive contact fixture may be disposed between at least two printed circuit boards (PCB) 134.

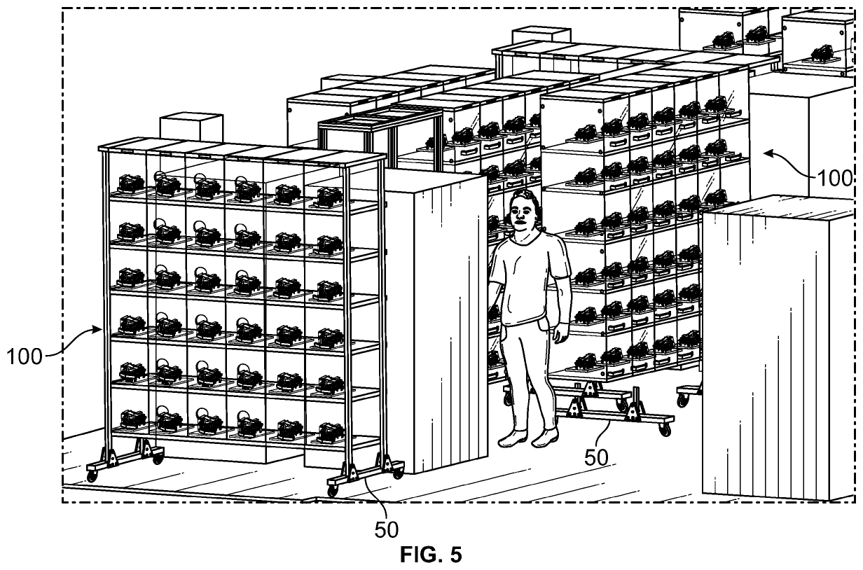

As illustrated in FIG. 5, in some embodiments, a user may utilize any number of testing apparatuses 100 to test a plurality of battery cells 10 at one time. For example, the testing apparatus 100 can be configured to be utilized in rack-mounted enclosures 50 (e.g., enclosures configured to cycle 64 batteries). In such embodiments, each rack-mounted enclosure 50 may contain a testing apparatus 100, and all testing apparatus 100 may be controlled by a central control system by remote access.

In some embodiments, the testing apparatus 100 includes sensors configured to measure cell voltage, charging and discharge rates of battery cell, and temperature of the battery cell. The process controller of the testing apparatus 100 may also provide information indicative of the state of the battery cell 10 to external devices (e.g., external computing devices, services, mobile devices, or the cloud) and receive instructions and information from such external devices.

In some embodiments, the ducted fan assemblies 150 may be further coupled to a controller and relay switches, the controller configured to send turn-on or shut-off signals to the ducted fan assemblies. In some embodiments, the controller may be the same as the process controller coupled to the relay switches of the thermoelectric junctions. In some embodiments, the controller may be configured to send turn-on or shut-off signals based on a predetermined temperature set point for the heat sinks. In some embodiments, the controller may be configured to adjust the speed of the ducted fans based on a predetermined temperature set point for the heat sinks.

In some embodiments, the thermoelectric junctions may be Peltier junctions. In such embodiments, the process controller may be configured to reverse the direction of current flow based on a predetermined temperature set point and a measured temperature.

In some embodiments, the process controller may be configured to use pulse-width modulation to vary the power applied to the thermoelectric junction plates 126. The process controller may be further configured to reverse the direction of current flow through the thermoelectric junction plates 126 to heat or cool the temperature control assemblies 120A-120C.

In some embodiments, any of the metals in the testing apparatus 100 may be any suitable high-conductivity material, including composite materials.

In some embodiments, the testing apparatus 100 may be configured so as to allow a user to remove individual components of the testing apparatus 100 to allow access to the battery cell 10 without full disassembly of the testing apparatus 100.

In some embodiments, a mounting assembly may be referred to as a mounting frame.

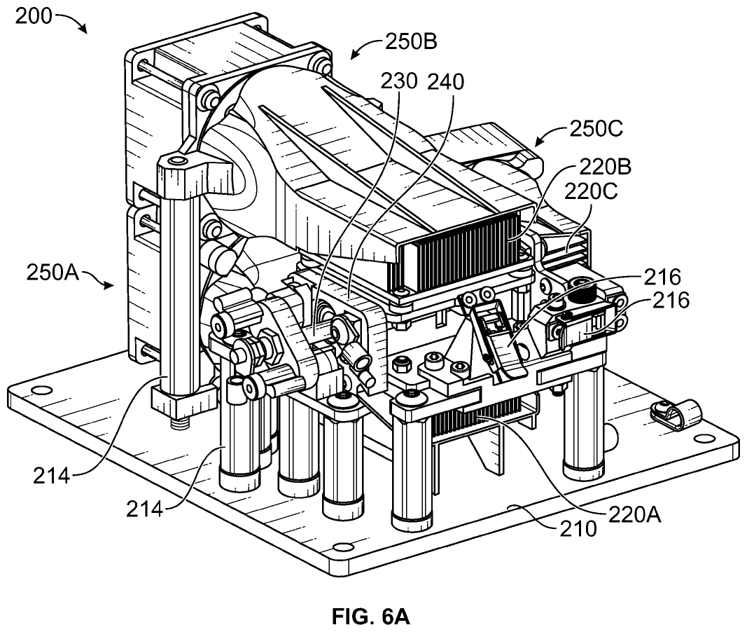

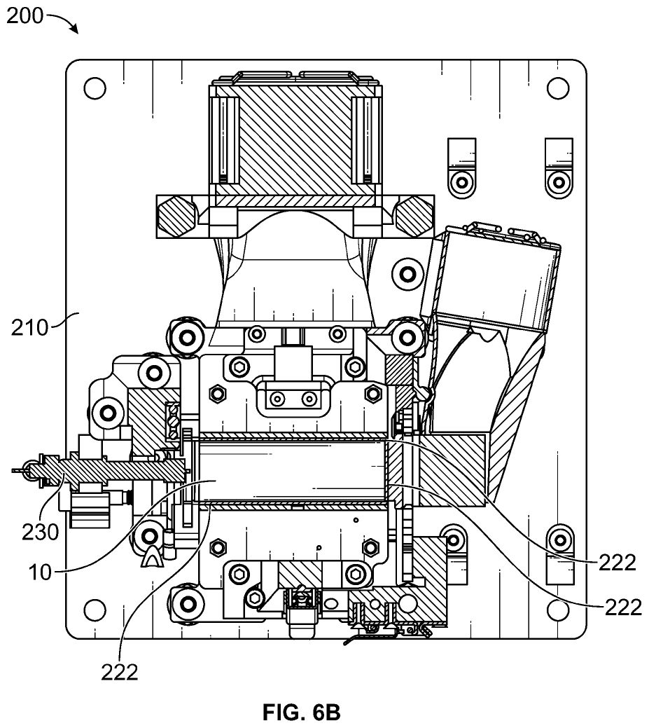

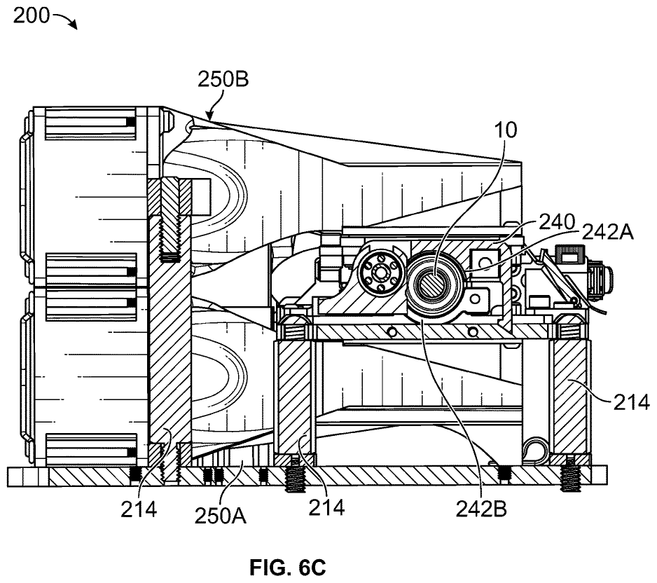

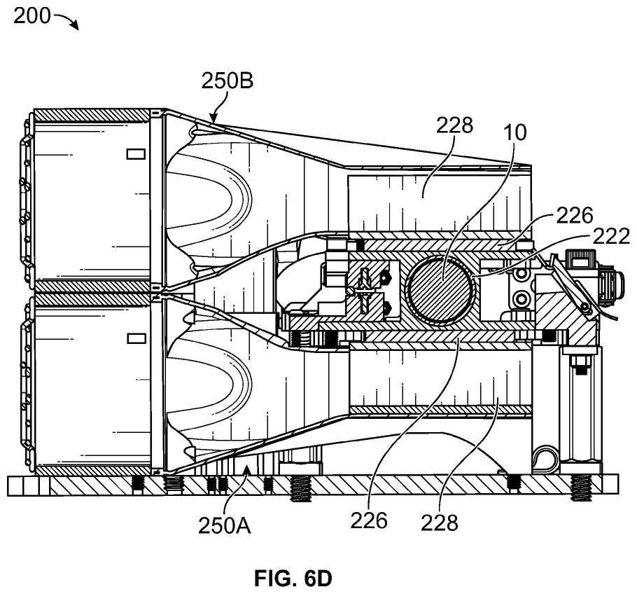

FIG. 6A illustrates a perspective view of a testing apparatus 200, according to exemplary embodiments of the present invention. In some embodiments, the testing apparatus 200 includes a base 210, one or more supports 214 coupled to the base 210, one or more latches 216, a positive contact fixture 230, a negative contact fixture 240, a lower temperature control assembly 220A, an upper temperature control assembly 220B, and a rear temperature control assembly 220C. A lower ducted fan assembly 250A may be coupled to the lower temperature control assembly 220A, an upper ducted fan assembly 250B may be coupled to the upper temperature control assembly 220B, and a rear ducted fan assembly 250C may be coupled to the rear temperature control assembly 220C. One or more components of the testing apparatus may be coupled to the base 210 and/or the supports 214 using a fastener. As shown, the supports 214 may elevate a component of the testing apparatus 200 a distance above the base 210, which may allow for improved temperature control capabilities of the testing apparatus 200 such as efficient placement of the lower temperature control assembly 220A.

The lower, upper, and rear temperature control assemblies 220A-220C may couple together, such as by use of the one or more latches 216, to define a cavity sized and shaped to receive the battery cell 10 for testing. The positive contact fixture 230 and the negative contact fixture 240 may be coupled to the supports 214 proximal to an opening (e.g., an exposed end) of the cavity. When the battery cell 10 is disposed in the testing apparatus 200, the positive contact fixture 230 and the negative contact fixture 240 may engage with a portion of the battery cell to facilitate testing operations, such as charging, discharging, and/or gathering test data.

FIG. 6B illustrates a top cross-sectional view of the testing apparatus of FIG. 6A having a battery cell 10 installed, according to exemplary embodiments of the present invention. As shown, when the battery cell 10 is installed in the testing apparatus 200, one or more surfaces of the battery cell 10 may be in contact with the TIM layer 222 of the temperature control assemblies 220A-220C. For example, where the battery cell 10 includes a first end, a second end, and a body disposed between the first and second end, the body and second end may be in contact with respective TIM layers 222 and the first end may be free. The positive contact fixture 230 may engage with a positive electrode on the first end of the battery cell 10 to carry out testing operations, such as charging and discharging of current to the battery cell 10 and/or obtaining voltage information (e.g., voltage measurement) of the battery cell 10. Similarly, the negative contact fixture 240, shown in FIG. 6A may also be engaged with a negative electrode on the first end of the battery cell 10. Contacting the first end of the battery cell 10 with the positive and negative contact fixtures 230 and 240 may allow for testing operations to mimic in-use applications of the battery cell 10 compared to contacting the battery cell on the first and second end.

FIG. 6C illustrates a side cross-sectional view of the testing apparatus 200 of FIG. 6A having the battery cell 10 installed, according to exemplary embodiments of the present invention. As shown, the one or more supports 214 may elevate various components of the testing apparatus 200 a vertical distance from the base 210, such as elevating the battery cell 10, the negative contact fixture 240, and/or the upper ducted fan assembly 250B. A distance of elevation may be sufficient to provide space for one or more other components of the testing apparatus 200 to be disposed below the battery cell 10. For example, the lower ducted fan assembly 250A may be disposed below the battery cell 10 to direct air flow to the lower temperature control assembly 220A. The negative contact fixture 240 is shown in a closed state and engaged with the battery cell 10. The negative contact fixture 240 may include an upper contact 242A and a lower contact 242B that circumferentially engage with a portion of the battery cell 10, such as a lip of the battery cell 10 proximal to the first end. The upper contact 242A and the lower contact 242B may provide voltage measurement information and/or charging and discharging of the battery cell 10.

FIG. 6D illustrates a side cross-sectional view of the testing apparatus 200 of FIG. 6A having the battery cell 10 installed, according to exemplary embodiments of the present invention. As shown, a surface of the battery cell 10 is in contact with the TIM layer 222 which facilitates the transfer of thermal energy to and/or from the thermoelectric junction plates 226. Thermal energy transferred to and/or from the thermoelectric junction plates 226 may be dissipated by respective heat sinks 228 coupled to the thermoelectric junction plates 226. The upper ducted fan assembly 250B may be in contact with the heat sink 228 of the upper temperature control assembly 220B and the lower ducted fan assembly 250A may be in contact with the heat sink 228 of the lower temperature control assembly 220A. The lower and upper ducted fan assemblies 250A and 250B may direct air flow over the respective heat sinks 228 to increase a rate of heat and/or moisture dissipation which may allow for more efficient temperature regulation of the testing apparatus 200.

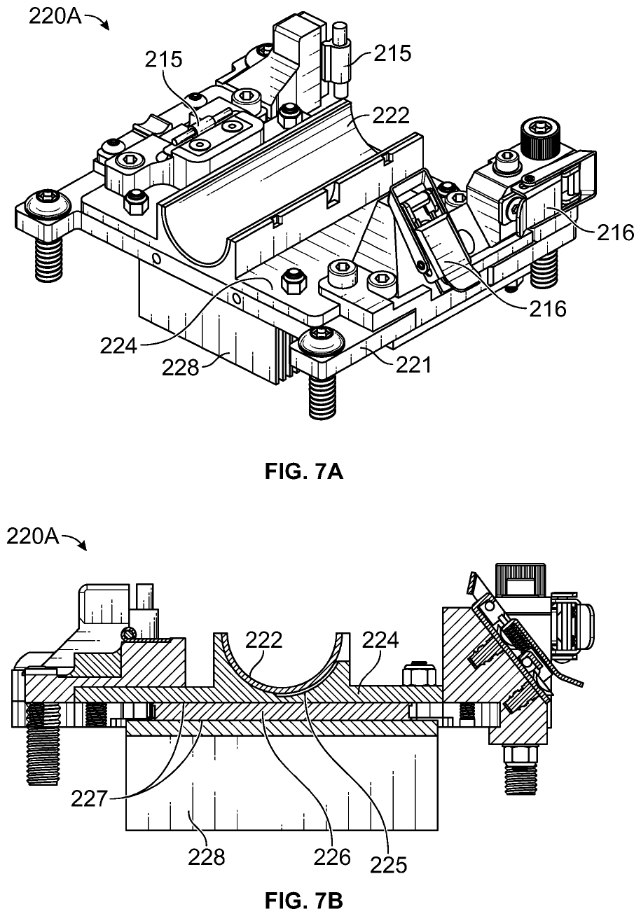

FIG. 7A illustrates a perspective view of the lower temperature control assembly 220A, according to exemplary embodiments of the present invention. The lower temperature control assembly 220A may facilitate temperature regulation of the battery cell 10 during testing operations. As shown, the lower temperature control assembly 220A includes a thermal interface material layer 222 coupled to a fixture 224, and a heat sink 228 coupled to the fixture 224. In some embodiments, one or more components of the lower temperature control assembly 220A may be coupled to a mount plate 221. For example, the fixture 224 may be coupled to the mount plate 221 which may facilitate coupling to the one or more supports 214 via a fastener (e.g., a threaded bolt).

In some embodiments, the lower temperature control assembly 220A may include one or more hinges 215 and/or the one or more latches 216. The one or more hinges 215 may provide rotatable coupling to the upper and/or rear temperature control assemblies 220B-220C, such that the upper and/or rear temperature control assemblies 220B-220C may pivot about the one or more hinges 215. Rotation of the upper and/or rear temperature control assemblies 220B-220C about the hinges 215 may allow for access to the cavity to facilitate installation and removal of the battery cell 10 during testing operations. The one or more latches 216 may be used to temporarily restrain movement of the upper and/or rear temperature control assemblies 220B-220C when coupled to the lower temperature control assembly 220A. For example, during testing operations the latches 216 may be engaged with a receiving portion on either the upper and/or rear temperature control assemblies 220B-220C to restrict undesirable pivoting while a test is being performed. The one or more hinges 215 and/or the one or more latches 216 may be coupled to the lower temperature control assembly using any suitable mounting structure, such as a three-dimensional printed mount having geometry that provides suitable spacing for the subsequently coupled components.

FIG. 7B illustrates a cross-sectional view of the lower temperature control assembly 220A of FIG. 7A, according to exemplary embodiments of the present invention. As shown, the lower temperature control assembly 220A may include one or more thermoelectric junction plates 226. The thermoelectric junction plates 226 may be disposed between the fixture 224 and the heat sink 228. In some embodiments, an adhesive, such as a thermal paste 227, may be disposed between respective surfaces of the fixture 224 and the thermoelectric junction plates 226 and/or respective surfaces of the heat sink 228 and the thermoelectric junction plates 226. The thermal paste 227 may facilitate coupling, and/or the transfer of thermal energy, between the thermoelectric junction plates 226 and the fixture 224 and/or the heat sink 228.

In some embodiments, the thermal interface material (TIM) layer 222 may be disposed on the surface of a respective metal fixture 224. One or more dimensions of the TIM layer 222 may be based on a mating component. For example, the size and shape of the TIM layer 222 may be defined by geometry of the battery cell 10 and/or the fixture 224. In some embodiments, the TIM layer 222 may be sufficiently flexible to conform to a surface of the fixture 224. Thus, the TIM layer 222 on the lower, upper, and/or rear temperature control assemblies 220A-220C may be sized and shaped to mirror a mating surface of the respective fixture 224 on the temperature control assembly. The TIM layer 222 may be made of any suitable material that facilitates efficient transfer of thermal energy between the battery cell 10 and the fixture 224. For example, the TIM layer 222 may include a silicone based material.

When the battery cell 10 is installed within the testing apparatus 200 a first surface of the TIM layer 222 may be in contact with the battery cell 10 and a second surface, opposite the first surface, may be in contact with the fixture 224. During some example testing operations, such as when cooling of the battery cell 10 is needed, the TIM layer 222 may transfer thermal energy (e.g., draw heat away) from the battery cell 10 to the fixture 224 for subsequent transfer to the thermoelectric junction plates 226 and/or the heat sink 228. During other example testing operations, such as when heating of the battery cell 10 is needed, the TIM layer 222 may transfer thermal energy (e.g., draw heat towards) to the battery cell 10 from the fixture 224 which may be supplied by the thermoelectric junction plates 226. Thus, the TIM layer 222 may assist in regulating the temperature of the battery cell 10 by transferring thermal energy between the fixture 224 and the battery cell 10.

The fixture 224 may be coupled to one or more components of the testing apparatus 200, such as the mount plate 221, and serve as a placement location of the battery cell 10 during testing operations. In some embodiments, a portion of the fixture 224 may be sized and shaped to receive a portion of the battery cell 10. For example, a portion of the fixture 224 on the lower temperature control assembly 220A may define an arcuate profile that aligns with geometry of the battery cell 10 such that the battery cell 10 may be cradled within the fixture 224. In such examples, the arcuate profile may resemble a cradle.

In some embodiments, it may be desirable for the fixture 224 to transfer thermal energy between the battery cell 10 and one or more components of the testing apparatus 200, such as the thermoelectric junction plates 226. In such examples, the fixture 224 may be made from a material having a high thermal conductivity, such as aluminum or copper, to efficiently transfer thermal energy between the battery cell 10 and the one or more components. The TIM layer 222 may be disposed on a first surface of the fixture 224 and the thermoelectric junction plates 226 may be disposed on a second surface of the fixture 224, opposite the first surface. During some example testing operations where cooling of the battery cell 10 is needed, the fixture 224 may transfer thermal energy from the TIM layer 222 to the thermoelectric junction plates 226 to reduce a temperature of the battery cell 10. During testing operations where heating of the battery cell 10 is needed, the fixture 224 may transfer thermal energy from the thermoelectric junction plates 226 to the TIM layer 222 to increase a temperature of the battery cell 10. Thus, in some embodiments the fixture 224 may facilitate temperature regulation of the battery cell 10 during testing operations through efficient transferring of thermal energy between the TIM layer 222 and the thermoelectric junction plates 226.

As shown, the fixture 224 may define a groove 225 along a portion of the fixture 224 proximal to the TIM layer 222. In some embodiments, the groove 225 may form a void (e.g., a gap, a channel, or a pocket) between the fixture 224 and the TIM layer 222. The groove 225 may allow for placement of a temperature measurement device, such as a sensor, a thermistor, a thermocouple, and the like. The temperature measurement device may be disposed within the groove 225 and couple to the fixture 224 and/or the TIM layer 222. In such examples, the temperature measurement device may sense thermal energy transferred from the battery cell 10 through the TIM layer 222. Placement of the temperature measurement device within the groove 225 may allow for accurate temperature data of the battery cell 10 to be gathered during testing operations, which may provide for improved temperature regulation of the battery cell 10. For example, the temperature measurement device may be coupled to a computing device in communication with a controller. In such examples, based on data received by the temperature measurement device, the controller may control operations of the thermoelectric junction plates 226 to provide heating and/or cooling to the battery cell 10. Thus, including the groove 225 proximal to a placement location of the battery cell 10 may allow for sensing equipment to be installed to accurately gather data from the battery cell 10 during testing.

In some embodiments, the thermoelectric junction plates 226 may be coupled between the fixture 224 and the heat sink 228. For example, a first surface of the thermoelectric junction plates 226 may be coupled to a surface of the fixture 224 and a second surface, opposite the first surface, of the thermoelectric junction plates 226 may be coupled to a surface of the heat sink 228. In some embodiments a thermal paste 227 may couple the thermoelectric junction plates 226 to the fixture 224 and/or the heat sink 228. The thermal paste 227 may aid in transferring thermal energy between the thermoelectric junction plates 226 and the fixture 224 and/or heat sink 228.

The thermoelectric junction plates 226 may be coupled to a power supply that supplies electrical power to the thermoelectric junction plates 226 for heating and/or cooling of the battery cell 10. For example, electrical current supplied by the power source may flow through the thermoelectric junction plates 226 which may cause a first junction to increase in temperature and a second junction to decrease in temperature. The temperature difference between the first and second junction may be used to provide heating and/or cooling to the battery cell 10.

In some embodiments, the thermoelectric junction plates 226 may be coupled to a controller (e.g., the process controller). The controller may control an amount of power, such as current, supplied to the thermoelectric junction plates 226, for example through one or more relay switches coupled to the thermoelectric junction plates 226. In such examples, the controller may control the amount of power supplied to the thermoelectric junction plates 226 based on a current temperature of the battery cell 10 and/or a determined testing temperature. The determined testing temperature may be a predetermined temperature set point, or predetermined temperature range, above or below which electrical power may be supplied to the thermoelectric junction plates 226. For example, when the current temperature of the battery cell 10 is outside of the determined testing temperature, the controller may control the power supply to provide electrical power to the thermoelectric junction plates 226 to provide heating and/or cooling in order to bring the temperature of the battery cell 10 within the determined testing temperature. In another example, when the current temperature of the battery cell 10 satisfies (e.g., reaches or exceeds) the predetermined temperature set point the controller may control the power supply to provide electrical power to the thermoelectric junction plates 226 to provide heating and/or cooling to the battery cell 10. Thus, the thermoelectric junction plates 226 may be controllable to provide heat to the battery cell 10 in a first instance and remove heat from the battery cell in a second instance.

In such examples, an amount of power supplied to the thermoelectric junction plates 226 may be based on inputs received by a temperature measurement device. For example, the controller may be coupled to the thermoelectric junction plates 226 and the temperature measurement device residing in the groove 225. However, in other examples the temperature measurement device may be located on another component of the lower temperature control assembly 220A. The controller may receive inputs (e.g., temperature data) from the temperature measurement device which may be used to determine an amount of electrical power and/or a direction of current flow to supply to the thermoelectric junction plates 226. For example, the inputs from the temperature measurement device may be the current temperature of the battery cell 10 which the controller may reference against the determined testing temperature, such as the predetermined temperature set point. Thus, the controller may reverse a direction of current flow to the thermoelectric junction plates 226 based on satisfying the predetermined temperature set point. In some embodiments, the controller may control the relay switches based on inputs received from the temperature measurement device.

In some embodiments, one or more of the thermoelectric junction plates 226 may be a Peltier junction.

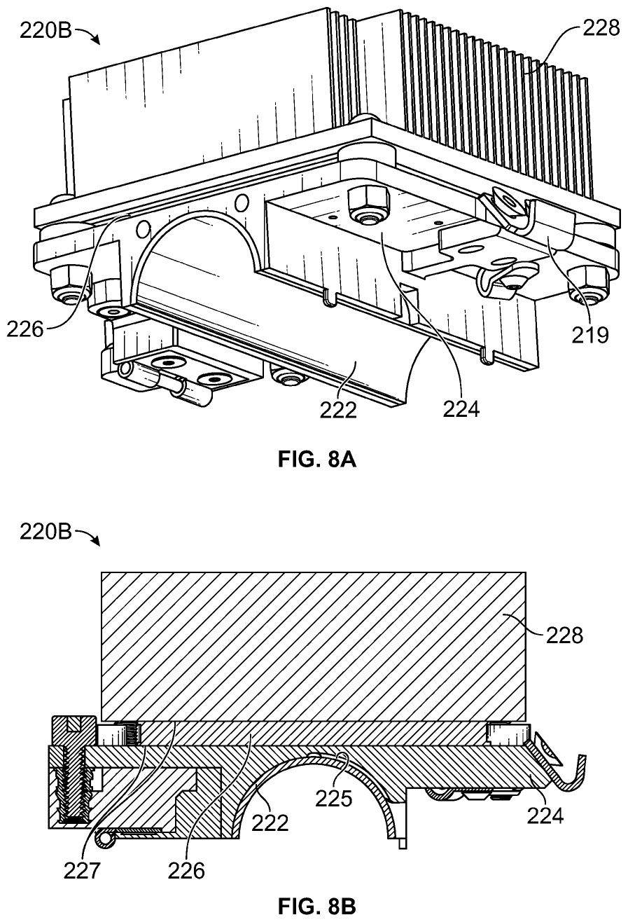

FIGS. 8A and 8B respectively illustrate a perspective view and a cross-sectional view of an upper temperature control assembly 220B, according to exemplary embodiments of the present invention. The upper temperature control assembly 220B may include a TIM layer 222 coupled to a fixture 224, thermoelectric junction plates 226 coupled on a first side to the fixture 228 and on a second side to a heat sink 228. Thermal paste 227 may be used to couple one or more of the components, such as coupling the thermoelectric junction plates 226 to the fixture 224. The upper temperature control assembly 220B may facilitate temperature regulation of the battery cell 10 during testing operations. For example, the upper temperature control assembly 220B may regulate the temperature of a portion of the body of the battery cell 10 in contact with the TIM layer 222. In some embodiments, the battery cell 10 may be disposed horizontally in the testing apparatus 200. In such examples, the TIM layer 222 of the upper temperature control assembly 220B may be in contact with an upper portion, such as an upper longitudinal half, of the body. A portion of the fixture 224 on the upper temperature control assembly 220B may define an arcuate profile that aligns with the geometry of the battery cell 10. When the upper temperature control assembly 220B is disposed over the battery cell 10 the upper temperature control assembly 220B may cradle the battery cell 10 within the fixture 224. In some embodiments, the portion of the fixture 224 on the upper temperature control assembly 220B that receives the battery cell 10 may mirror geometry of the fixture 224 on the lower temperature control assembly 220B that receives the battery cell 10.

The upper temperature control assembly 220B may include a clasp and/or a hinge which may allow for coupling to the lower temperature control assembly 220A. For example, the upper temperature control assembly 220B may be rotatably coupled to the hinge 215 of lower temperature control assembly 220A to facilitate installation and removal of the battery cell 10, and/or lockingly coupled to the latch 216 for securing the upper temperature control assembly 220B to the lower temperature control assembly 220A during testing operations. One or more components of the upper temperature control assembly 220B may be the same as and/or similar to one or more components of the lower temperature control assembly 220A. Thus, the form and/or function of the one or more components described for the lower temperature control assembly 220A may be equally applicable to the one or more components of the upper temperature control assembly 220B.

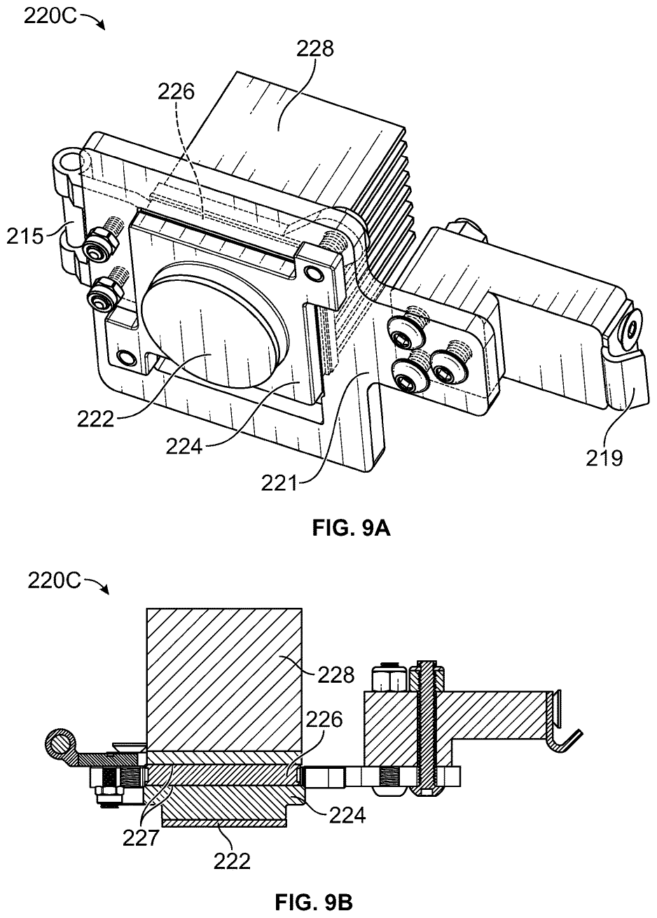

FIGS. 9A and 9B respectively illustrate a perspective view and a cross-sectional view of the rear temperature control assembly 220C, according to exemplary embodiments of the present invention. The rear temperature control assembly 220C may include a TIM layer 222 coupled to a fixture 224, thermoelectric junction plates 226 coupled on a first side to the fixture 228 and on a second side to a heat sink 228. Thermal paste 227 may be used to couple one or more of the components, such as coupling the thermoelectric junction plates 226 to the fixture 224. The rear temperature control assembly 220C may facilitate temperature regulation of the battery cell 10 during testing operations. For example, the rear temperature control assembly 220C may regulate the temperature of a portion of the body of the battery cell 10 in contact with the TIM layer 222. In some embodiments, the battery cell 10 may include a first end and a second end, opposite the first end, where the first end includes a positive electrode and a lip that includes a negative electrode. In such examples, the TIM layer 222 of the rear temperature control assembly 220C may be in contact with an end, such as the second end, of the battery cell 10. A portion of the fixture 224 on the rear temperature control assembly 220C may mirror geometry of the mating surface of the battery cell 10, such as mirroring a profile of the second end. When the rear temperature control assembly 220C is engaged with the battery cell 10, the rear temperature control assembly 220C may retain the second end of the battery cell 10 within the fixture 224.

The rear temperature control assembly 220C may include a clasp and/or a hinge which may allow for coupling to the lower temperature control assembly 220A. For example, the rear temperature control assembly 220C may be rotatably coupled to the hinge 215 of lower temperature control assembly 220A to facilitate installation and removal of the battery cell 10, and/or lockingly coupled to the latch 216 for securing the rear temperature control assembly 220C to the lower temperature control assembly 220A during testing operations. One or more components of the rear temperature control assembly 220C may be the same as and/or similar to one or more components of the lower and/or upper temperature control assemblies 220A and 220B. Thus, the form and/or function of the one or more components described for the lower and/or upper temperature control assemblies 220A and 220B may be equally applicable to the one or more components of the rear temperature control assembly 220C.

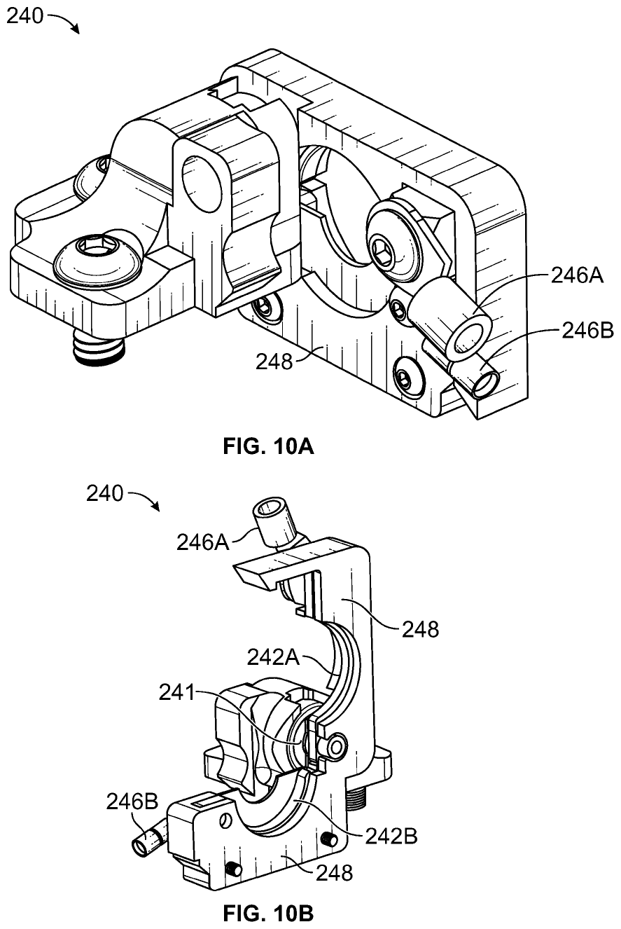

FIGS. 10A and 10B illustrate perspective views of a negative contact fixture 240, according to exemplary embodiments of the present invention. FIG. 10A shows the negative contact fixture 240 in a closed position, while FIG. 10B shows the negative contact fixture 240 in an opened position. The negative contact fixture 240 includes a frame 248, an upper contact 242A, and a lower contact 242B. The negative contact fixture 240 may be coupled to the one or more supports 214 of the testing apparatus 200 by way of the frame 248. In some embodiments, the negative contact fixture 240 may be disposed on the testing apparatus 200 proximal to the positive contact fixture 230. The frame 248 may include of one or more portions coupled together. For example, the frame 248 may include an upper portion coupled to a lower portion at a pivot 241. The upper portion of the frame 248 may rotate about the pivot 241 between the closed position, shown in FIG. 10A, and the opened position, shown in FIG. 10B.

In some embodiments, the upper contact 242A may be disposed on the upper portion of the frame 248 and the lower contact 242B may be disposed on the lower portion of the frame 248, such that the upper contact 242A may rotate about the pivot 241 between the opened and closed positions. The negative contact fixture 240 may be actuated between the opened and closed positions to allow insertion and/or removal of the battery cell 10. For example, the battery cell 10 may be inserted and/or removed from the negative contact fixture 240 while in the opened position and testing operations may be performed on the battery cell 10 when the negative contact fixture 240 is in the closed position.

When the negative contact fixture 240 is in the closed position, the upper contact 242A and the lower contact 242B may be engaged with a portion of the battery cell 10, such as engaged with a lip of the battery cell 10. The lip of the battery cell 10 may include a negative electrode which the upper and lower contacts 242A and 242B may be engaged with. In some embodiments, the battery cell 10 includes a first end and a second end opposite the first end, where the lip of the battery cell 10 is proximal to the first end and the first end includes the positive electrode. In such examples, the upper contact 242A and the lower contact 242B may contact the battery cell 10 at, or proximal to, the first end. Contacting the battery cell 10 at, or proximal to, the first end may allow for the negative contact fixture 240 to replicate in-service use conditions of the battery cell 10 during testing.

As shown, a portion of the upper contact 242A and/or the lower contact 242B may be defined by an arcuate profile, such as a curve or semicircular arch. The arcuate profile on the upper contact 242A and/or the lower contact 242B may be sized and shaped to engage with a perimeter of the battery cell 10, such as the lip of the battery cell 10. In some embodiments, it may be desirable to maximize surface contact between battery cell 10 and the upper contact 242A and/or the lower contact 242B. In such examples, one or more dimensions of the arcuate profile defined by the upper contact 242A and/or the lower contact 242B may be less than the perimeter of the battery cell 10. For example, the arcuate profile of the upper contact 242A and/or the lower contact 242B may be defined by a first radius and the perimeter of the battery cell 10 may be defined by a second radius, where the first radius is less than the second radius. In such examples, when the negative contact fixture 240 is in the closed position a circular shaped perimeter defined by the upper and lower contacts 242A and 242B may be less than a circular perimeter defined by the battery cell 10, such that when the battery cell 10 is installed in the negative contact fixture 240 an interference fit exists between the battery cell 10 and the upper and lower contacts 242A and 242B. An interference fit between the battery cell 10 and the upper and lower contacts 242A and 242B may provide an optimal amount of surface contact between the respectively engaged parts which may allow for more accurate testing of the battery cell 10 to occur.

In some embodiments, the upper contact 242A and/or the lower contact 242B may be elastically deformable about the battery cell 10, such as the lip of the battery cell 10. For example, the upper contact 242A and/or the lower contact 242B may be made from a material that elastically deforms about the perimeter of the battery cell 10 when the negative contact fixture 240 is in the closed position. In such examples, the upper contact 242A and/or the lower contact 242B may be defined by the first radius and the perimeter of the battery cell 10 may be defined by the second radius to allow elastic deformation to occur. Elastically deforming the upper contact 242A and/or the lower contact 242B about the battery cell 10 may allow for improved surface contact between the negative contact fixture 240 and the battery cell 10 compared to a non-deformable contact fixture.

In some embodiments, electrical conductivity of the upper contact 242A and/or the lower contact 242B may be advantageous. Thus, the upper contact 242A and/or the lower contact 242B may be made from a material that allows for elastic deformation and/or electrical conductivity with the battery cell 10. In such examples, the upper contact 242A and/or the lower contact 242B may be made from a conductive metal or metal alloy, such as an aluminum or a copper based metal, however any suitable material may be used. Using an electrically conductive material that elastically deforms about the perimeter of the battery cell 10 may allow for improved interaction between the negative contact fixture 240 and the battery cell 10 which may improve the performance of testing operations.

In some embodiments, the negative contact fixture 240 may include one or more terminals, such as a large ring terminal 246A and a small ring terminal 246B. The large ring terminal 246A may be coupled to the upper contact 242A and the small ring terminal 246B may be coupled to the lower contact 242B. To facilitate coupling of the terminals, the upper contact 242A, the lower contact 242B, and/or the frame 248 may include one or more apertures sized and shaped to receive (e.g., engage with) a portion of the large ring terminal 246A and/or the small ring terminal 246B.

Each of the large ring terminal 246A and the small ring terminal 246B may be coupled to one or more electrical wires to carry out testing operations. For example, the large ring terminal 246A may be coupled to the upper contact 242A to facilitate charging and/or discharging of the battery cell 10. In examples where the large ring terminal 246A facilitates charging and/or discharging of the battery cell 10, the one or more wires coupled to the large ring terminal 246A may transmit electricity between the large ring terminal 246A and a power source or power sink. In some embodiments, the small ring terminal 246B may be coupled to the lower contact 242B to facilitate voltage measurement of the battery cell 10. In such examples, the one or more wires coupled to the lower contact 242B may transmit voltage measurement data gathered from the battery cell 10 to a voltage measurement device. However, in other embodiments the large ring terminal 246A may be used for voltage measurement and the small ring terminal 246B may be used for charging and/or discharging of the battery cell 10. A position of the large ring terminal 246A and the small ring terminal 246B may be rotatable about a coupling point with the upper and lower contacts 242A and 242B to allow coupling of the one or more wires in a manner that does not obstruct additional components of the testing apparatus 200.

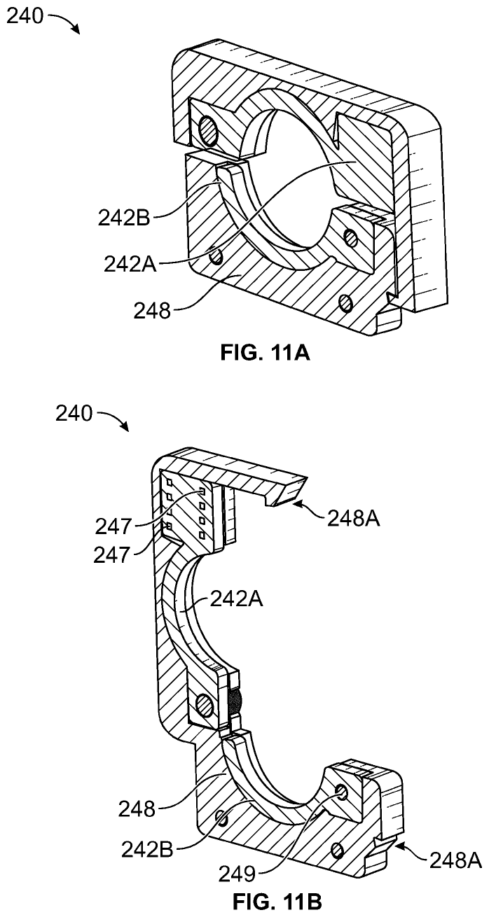

FIGS. 11A and 11B illustrate perspective views of a portion of the negative contact fixture 240 of FIGS. 10A and 10B, according to exemplary embodiments of the present invention. FIG. 11A shows the portion of the negative contact fixture 240 in the closed position, while FIG. 11B shows the portion of the negative contact fixture 240 in the opened position. As illustrated in FIGS. 11A and 11B the upper contact 242A and the lower contact 242B are coupled to the frame 248. A portion of the frame 248 may be recessed such that when coupled a surface of the upper contact 242A and/or the lower contact 242B is flush with a surface of the frame 248.

The frame 248 may include an integrally formed latch portion 248A and an integrally formed latch receiver portion 248B. The latch portion 248A may be configured to engage with the latch receiver portion 248B, such as when the negative contact fixture 240 is in the closed position. The latch portion 248A may lockingly engage with the latch receiver portion 248B to retain the negative contact fixture 240 in the closed position. In some embodiments, the frame 248 may be made from an elastically deformable material, such as a polymer. Using an elastically deformable material for the frame 248 may allow for the latch portion 248A to be engaged and/or disengaged with the latch receiver portion 248B without the use of additional hardware. However, in other embodiments another locking mechanism may be used, such as the latch 216.

In some embodiments, the upper contact 242A may include one or more upper contact apertures 247. The upper contact apertures 247 may facilitate coupling between the upper contact 242A and the large ring terminal 246A. As shown in FIG. 11B, the upper contact 242A includes eight upper contact apertures 247, however in other examples another number of apertures may be used. For example, between 1 and 4 upper contact apertures, between 4 and 8 upper contact apertures, between 8 and 12 upper contact apertures, and between 12 and 16 upper contact apertures may be used. While the upper contact apertures 247 shown in FIG. 11B have a polygonal shape (e.g., a square shape), in other examples the upper contact apertures 247 may be another suitable shape for mating with the large ring terminal 246A, such as circular.

In some embodiments, the lower contact 242B may include one or more lower contact apertures 249. The lower contact apertures 249 may facilitate coupling between the lower contact 242B and the small ring terminal 246B. As shown in FIG. 11B, the lower contact 242B includes one lower contact aperture 249 having a circular shape, however in other examples another number of apertures may be used. For example, between 1 and 2 lower contact apertures, between 2 and 4 lower contact apertures, between 4 and 6 lower contact apertures, and between 6 and 8 lower contact apertures may be used. Further, the lower contact apertures 249 may have any suitable shape for mating with the small ring terminal 246B, such as a polygonal shape. The upper contact and lower contact apertures 247 and 249 may allow for test measurement data to be gathered from the battery cell 10 during testing operations and/or for charging and discharging of the battery cell 10.

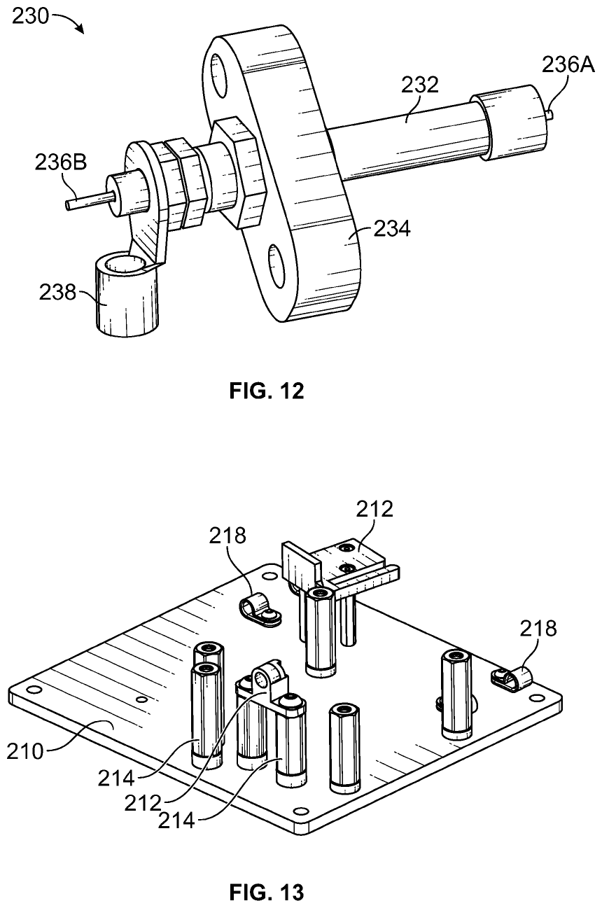

FIG. 12 illustrates a perspective view of the positive contact fixture 230, according to exemplary embodiments of the present invention. The positive contact fixture 230 may include a positive contact 232, a mounting bracket 234, a center probe 236A, a pin 236B, and a ring terminal 238. The positive contact 232 may be coupled to the mounting bracket 234 which may provide coupling to the support 214 and/or another component of the testing apparatus. For example, the positive contact 232 may be disposed in an aperture of the mounting bracket 234 such that a first end of the positive contact 232 is on a first side of the mounting bracket 234 and a second end of the positive contact 232 is on a second side of the mounting bracket 234, opposite the first side.

The positive contact 232 may be movable on the testing apparatus 200 such that in a first position the positive contact 232 is engaged with the battery cell 10 and in a second position the positive contact 232 is disengaged with the battery cell 10. In some embodiments, the positive contact 232 may contact a surface of the battery cell 10. For example, the positive contact 232 may be engaged with a positive electrode of the battery cell 10, which may be at the first end of the battery cell 10 proximal to the lip portion engaged by the negative contact fixture 240. As shown, the positive contact fixture 230 includes a single positive contact. A diameter of the positive contact 232 may be up to and/or exceeding a diameter of the battery cell 10. Increasing a diameter of the positive contact 232, compared to using multiple smaller diameter positive contacts, may increase an amount of thermal mass available to more effectively draw away heat generated from contact resistance. Further, increasing the diameter of the positive contact 232 may provide more efficient charging and/or discharging of current to the battery cell 10. In some embodiments, the positive contact 232 may be made from one or more electrically conductive materials. For example, the positive contact 232 may include a gold plating.

In some embodiments, the center probe 236A may be disposed at an end of the positive contact 232, such as the first end of the positive contact 232. The center probe 236A may protrude outwardly from the positive contact 232 along a longitudinal axis defined by the body of the positive contact 232. In some embodiments, the center probe 236A may engage with the positive electrode of the battery cell 10 to obtain information during testing operations. For example, the center probe 236A may be used to obtain and/or measure voltage information about the battery cell 10. The center probe 236A may include a spring such that that the center probe 236A depresses when engaged with the battery cell 10 and extends when disengaged from the battery cell 10. A spring actuated center probe may allow for constant contact to occur between the center probe 236A and the battery cell 10 which may increase the accuracy of measurements taken by the center probe 236A. The spring actuated center probe may further allow for a surface of the positive contact 232 to fully engage with a surface of the battery cell 10 which may provide for improved charging and/or discharging of current from the battery cell 10.

The pin 236B may be disposed at an end of the positive contact 232, such as the second end of the positive contact 232. The pin 236B may protrude outwardly from the positive contact 232 along the longitudinal axis in a direction opposite the center probe 236A. In some embodiments, the pin 236B may be disposed along a same axis as the center probe 236A such that the pin 236B is in-line with the center probe 236A. In such examples, the pin 236B may be connected to the center probe 236A. The pin 236B may allow for voltage measurements, received by the center probe 236A, to occur.

The ring terminal 238 may include an aperture for coupling to the positive contact 232. For example, the ring terminal 238 may be disposed on the positive contact 232 by way of the aperture. In some embodiments, one or more wires may couple to the ring terminal to allow for charging or discharging of the battery cell 10 to occur through the positive contact 232 and/or to enable test measurement data (e.g., voltage and/or current measurement data) to be transmitted to a measurement device.

FIG. 13 illustrates a perspective view of a base 210 of the testing apparatus 200 of FIG. 6A, according to exemplary embodiments of the present invention. As shown, one or more supports 214 and/or one or more clamps 218 may be coupled to the base 210. Mounting units 212 (e.g., a mounting frame) may couple to the one or more supports 214. The base 210, the one or more supports 214, and/or the mounting units 212 may serve as mounting locations for various components of the testing apparatus 200, such as one or more of the temperature control assemblies 220A-220C, the positive contact fixture 230, the negative contact fixture 240, and the ducted fan assemblies 250A-250C.

In some embodiments, the one or more supports 214 and/or the one or more clamps 218 may be coupled to the base 210 using a fastener (e.g., a bolt). For example, the one or more supports 214 and the base 210 may each include a threaded hole such that a fastener may be inserted through the threaded holes to couple the one or more supports 214 to the base 210. In some embodiments, the one or more supports 214 may include a threaded hole for coupling to the mounting units 212, such that the one or more supports 214 may be coupled at a first end to the base 210 and at a second end to the mounting units 212. The mounting units 212 and the one or more supports 214 may elevate various components of the testing apparatus 200 a vertical distance from the base 210 which may increase an amount of temperature control capability around all sides of the battery cell 10 and/or allow for the unobstructed addition of components below the battery cell 10, such as the lower temperature control assembly 220A. The one or more clamps 218 may be placed at locations on the base 210 where cable management is advantageous. For example, it may be desirable to control a position or orientation of cables coupled to the testing apparatus 200 so as not to obstruct testing operations. In such examples, the one or more clamps 218 may provide a retaining mechanism for organizing cables or other hardware of the testing apparatus 200. Thus, the base 210, the mounting units 212, the one or more supports 214, and the clamps 218 may provide an organized layout while allowing for optimum placement of various components of the testing apparatus 200 which may increase accuracy of test data.

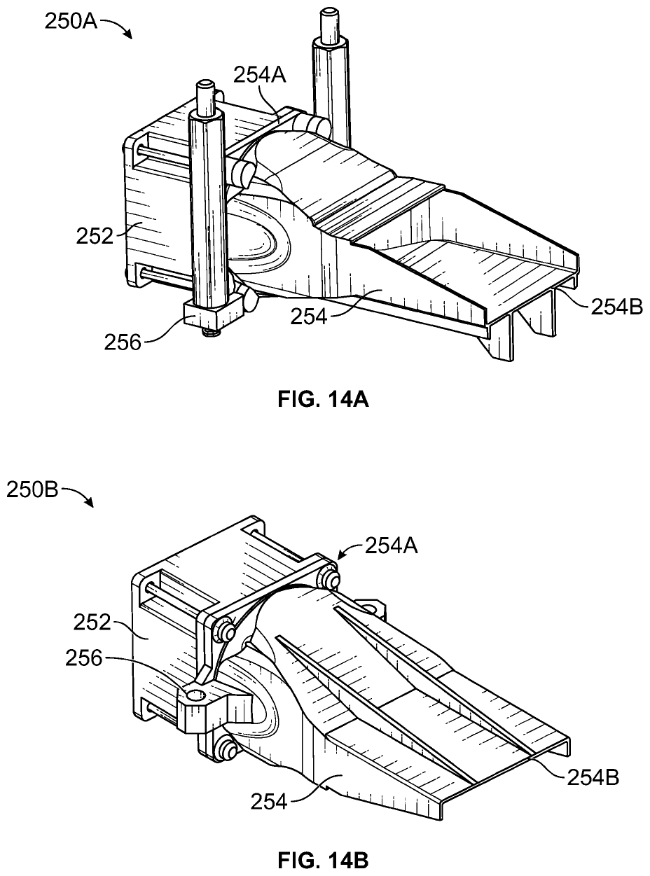

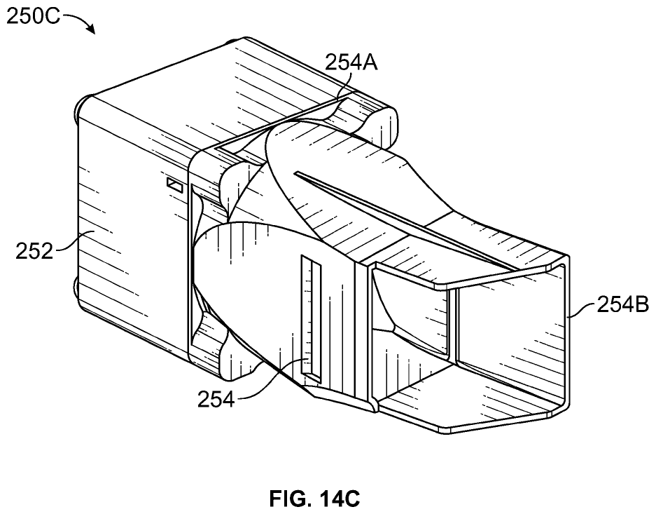

FIGS. 14A-14C respectively illustrate perspective views of a lower ducted fan assembly 250A, an upper ducted fan assembly 250B, and a rear ducted fan assembly 250C, according to exemplary embodiments of the present invention. Each of the lower ducted fan assembly 250A, the upper ducted fan assembly 250B, and the rear ducted fan assembly 250C may include a fan 252 and a fan duct 254 coupled to the fan 252. The fan 252 may include an inlet portion, one or more fan blades, a motor, and an outlet portion, where the motor actuates the fan blades to draw air in from the inlet portion and output air from the outlet portion. The fan duct 254 may include a first end 254A, a second end 254B opposite the first end 254A, and one or more attachment points 256 for coupling to supports 214 and/or the fan 252. The first end 254A may be coupled to the fan 252, such as the outlet portion, to receive output air and the second end 254B may be in communication with a heat sink to direct the output air over the heat sink. For example, the second end 254B of the fan duct 254 on the lower ducted fan assembly 250A may be coupled to the heat sink 228 on the lower temperature control assembly 220A; the second end 254B of the fan duct 254 on the upper ducted fan assembly 250B may be coupled to the heat sink 228 on the upper temperature control assembly 220B; and/or the second end 254B of the fan duct 254 on the rear ducted fan assembly 250C may be coupled to the heat sink 228 on the rear temperature control assembly 220C.

In some embodiments, each of the lower ducted fan assembly 250A, the upper ducted fan assembly 250B, and the rear ducted fan assembly 250C may supply and/or direct air flow over the respective heat sink. Supplying and/or directing air flow over the respective heat sinks may allow for temperature and/or moisture regulation of the testing apparatus 200. For example, when heat is being transferred from the battery cell 10 through the temperature control assemblies, the heat sinks 228 may function to dissipate heat from the thermoelectric junction plates 226. In such examples, directing air flow (e.g., ambient air) over the heat sinks 228 may increase a rate of heat dissipation capabilities allowing for more efficient functioning of the temperature control assemblies. In another embodiment, when heat is being transferred to the battery cell 10 from the temperature control assemblies, the heat sinks 228 may experience cooling from the thermoelectric junction plates 226. In such examples, directing air flow over the heat sinks 228 may decrease an amount of moisture (e.g., condensation) that may accumulate due to cooling and/or increase a temperature of the heat sinks 228 to allow the thermoelectric junction plates 226 to function more efficiently. Thus, the ducted fan assemblies 250A-250C may direct air over the heat sinks 228, via the fan ducts 254, which may allow for proper temperature and/or moisture regulation of the temperature control assemblies.

The ducted fan assemblies 250A-250C may each be coupled to a power supply configured to supply power to the fan 252. In some embodiments, each of the lower ducted fan assembly 250A, the upper ducted fan assembly 250B, and the rear ducted fan assembly 250C may be coupled to a controller, such as the process controller. The controller may independently control an amount of power supplied to each of the fans 252 of the ducted fan assemblies 250A-250C. For example, the each of the ducted fan assemblies 250A-250C may be controlled between an “off” state, indicating power is not being supplied to the fan 252 for operation, and an “on” state, indicating power is being supplied to the fan 252 for operation. In some embodiments, the controller may variably control an operating speed of the fan 252, such as controlling an amount of revolutions per minute (RPM) of the blades. In such examples, the controller may vary a non-zero amount of power supplied to the fan 252 based on a predetermined fan speed (e.g., an RPM rate of the fan 252).

In some embodiments, the lower ducted fan assembly 250A, the upper ducted fan assembly 250B, and the rear ducted fan assembly 250C may each be coupled to a sensor, such as a temperature measurement device. The sensor may receive temperature information about one or more components of the respective temperature control assemblies 220A-220C and/or the battery cell 10 which may be used to control operation of the ducted fan assemblies 250A-250C. For example, a fan speed of the ducted fan assemblies 250A-250C may vary based on temperature data for the heat sink 228 received from the sensor. In such examples, the fan speed may be increased or decreased by the controller (e.g., the process controller) if a predetermined temperature set point of the heat sink 228 is satisfied. The predetermined temperature set point may be based on a type of test being performed on the battery cell 10, such that the predetermined temperature set point may vary from a first test to a second test. In some embodiments, the temperature set point for the heat sink 228 is a set temperature range such that when the temperature data received is outside of the set temperature range the fan speed may be increased and/or decreased until the temperature data is within the set temperature range. Thus, the controller may independently control a fan speed of each of the ducted fan assemblies 250A-250C based on satisfying a predetermined temperature set point for the respective heat sink 228.

While in some embodiments the ducted fan assemblies 250A-250C receive and direct ambient air over the respective temperature control assemblies 220A-220C, in other embodiments the ducted fan assemblies 250A-250C may receive non-ambient air or another gas. Non-ambient air may be referred to as conditioned air. For example, each of the fans 252 may be configured to receive above ambient air, such as heated air, and/or below ambient air, cooled air, from an air supply. The ducted fan assemblies 250A-250C may direct the conditioned air over the respective heat sink 228 in a similar manner as ambient air. In such examples, a type of conditioned air received by the fan 252 may be based on temperature data received from the sensor. For example, upon satisfying the predetermined temperature set point, above ambient air may be supplied to the fan 252 when heating of the heat sink 228 is needed, and below ambient air may be supplied to the fan 252 when cooling of the heat sink 228 is needed. Supplying conditioned air to the ducted fan assemblies 250A-250C may increase a rate of heating and/or cooling of the heat sink 228 which may increase overall operating efficiency of the temperature control assemblies 220A-220C.

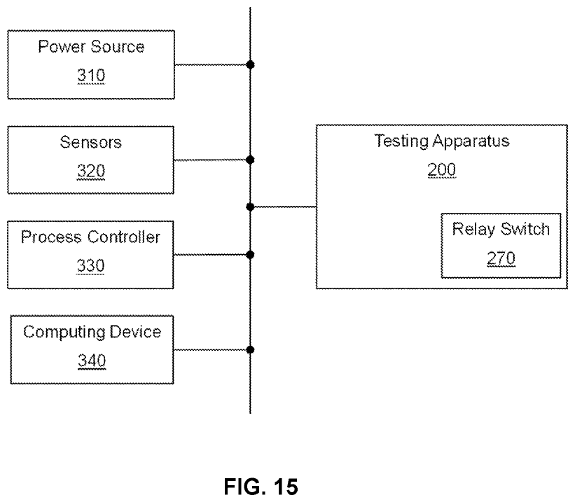

FIG. 15 illustrates a simplified box diagram of various components coupled to the testing apparatus 200, according to exemplary embodiments of the present invention. As shown, the testing apparatus 200 includes a relay switch 270, and may be coupled to a power source 310, one or more sensors 320, a process controller 330, and/or a computing device 340. In some examples, the testing apparatus 100 may be coupled to the same and/or similar components.

The testing apparatus 200 may be coupled to the power source 310 by way of one or more electrical wires. The power source 310 may supply power, such as electrical energy, to one or more components of the testing apparatus 200. For example, the power source 310 may supply power to the positive contact fixture 230, the negative contact fixture 240, the temperature control assemblies 220A-220B, and/or the ducted fan assemblies 250A-250C. In some embodiments, the power source 310 may be a wall mounted power outlet, while in other embodiments the power source 310 may be a standalone unit, such as a generator.

The one or more sensors 320 may be coupled to various components of the testing apparatus 200, such as the temperature control assemblies 220A-220C. The one or more sensors 320 may be configured to measure voltage of the battery cell 10, charging and discharge rates of the battery cell 10, temperature of the battery cell 10, and/or temperature of the temperature control assemblies 220A-220C. In some embodiments, each temperature control assembly 220A-220C may include the one or more sensors 320. For example, each of the lower temperature control assembly 220A, the upper temperature control assembly 220B, and the rear temperature control assembly 220C may include a sensor disposed on each of the fixture 224, the thermoelectric junction plates 226, and/or the heat sink 228. In some embodiments, the one or more sensors 320 may include a temperature sensor (e.g., a temperature measurement device), a thermocouple, a thermistor, and the like. The one or more sensors 320 may sense temperature information about the battery cell 10 and/or the temperature control assemblies 220A-220C.

In some embodiments, information obtained by the one or more sensors 320 may be used to control operations of the temperature control assemblies 220A-220C and/or the ducted fan assemblies 250A-250C. For example, where the temperature control assemblies 220A-220C include the relay switch 270, the one or more sensors 320 may be coupled to the process controller 330 such that the process controller 330 controls the relay switches 270 based on inputs received from the one or more sensors 320. In another example, the one or more sensors may each be coupled to a respective temperature control assembly 220A-220C and the process controller 330, where the process controller 330 is further coupled to each of the ducted fan assemblies 250A-250C. In such examples, the process controller 330 may control a fan speed of a respective ducted fan assembly 250A-250C based on sensed temperature data from the heat sink 228 satisfying a predetermined temperature set point. Thus, information obtained by the one or more sensors 320 may be used to control and/or monitor operations of the testing apparatus 200 and/or the battery cell 10.

The process controller 330 may be coupled to one or more of the power source 310, the one or more sensors 320, the computing device 340, and/or the testing apparatus 200. In some embodiments, the process controller 330 may provide information indicative of the state of the battery cell 10 to external devices (e.g., external computing devices, services, mobile devices, or the cloud) and/or receive instructions and information from such external devices. The process controller 330 may be configured to send turn-on or shut-off signals to one or more components of the testing apparatus 200, such as the temperature control assemblies 220A-220C and/or the ducted fan assemblies 250A-250C. For example, the process controller 330 may be configured to send turn-on or shut-off signals to one or more components of the temperature control assemblies 220A-220C and/or the ducted fan assemblies 250A-250C based on a predetermined temperature set point for the fixtures 224, the thermoelectric junction plates 226, and/or the heat sinks 228. In such examples, the process controller 330 may be configured to adjust a speed of one or more of the ducted fan assemblies 250A-250C based on satisfying a predetermined temperature set point for the heat sinks 228.

In examples where the thermoelectric junction plates 226 include a Peltier junction, the process controller 330 may reverse a direction of current flow to the Peltier junction based on satisfying a predetermined temperature set point, such as a sensed temperature of the battery cell 10 satisfying the predetermined temperature set point. In some embodiments, the process controller 330 may be a pulse width modulation (PWM) controller. In such examples, the PWM controller may vary an amount of non-zero power supplied to the thermoelectric junction plates 226. Thus, the process controller 330 may facilitate testing operations of the battery cell 10 by controlling one or more components of the testing apparatus 200 based on received inputs.

The computing device 340 may be coupled to one or more of the power source 310, the sensors 320, the process controller 330, and/or the testing apparatus 200. The computing device 340 may be a mobile computing device (e.g., a smartphone), a desktop computing device, a laptop computing device, a tablet computing device, or a wearable computing device (e.g., a smartwatch or a smart wristband). In some embodiments, the computing device 340 may be part of the testing apparatus 200. The computing device 340 may send and receive information over one or more networks (e.g., the public Internet) or through one or more communication cables. In some embodiments, the computing device 340 may include a wired interface, such as Ethernet, or a wireless interface, such as WIFI.

In some embodiments, the computing device 340 may communicate with one or more of the power source 310, the sensors 320, the process controller 330, and/or the testing apparatus 200 to carry out testing operations of the battery cell 10. The computing device 340 may include a processor and a data storage that includes a non-transitory computer-readable medium, having stored thereon program instructions that, when executed by the processor, cause the processor to carry out any of the methods, processes, or operations disclosed in this specification and/or accompanying drawings.

For example, the computing device 340 may carry out instructions for a method for testing a battery cell using a testing apparatus (e.g., the testing apparatus 200), where the method includes placing the battery cell into the testing apparatus, where the battery cell contacts a surface of the thermal interface material of each of the plurality of temperature control assemblies. The method may also include positioning a positive contact of the testing apparatus in contact with a positive electrode of the battery cell. The method may additionally include positioning a negative contact of the testing apparatus in contact with a negative electrode of the battery located proximal to the positive electrode, wherein the negative contact elastically deforms to a surface of the battery. The method may further include controlling, using a process controller coupled to the thermoelectric junction, a temperature of the battery by controlling current flow through the thermoelectric junction. Thus, in some embodiments the computing device 340 may facilitate the execution of testing operations of the battery cell 10 within the testing apparatus 200 and/or receive testing information from the testing apparatus 200.

Implementations of the present disclosure can thus relate to one of the example embodiments listed below.

Embodiment 1 is a testing apparatus comprising: a base; a mounting frame comprising a plurality of supports coupled to the base; a plurality of temperature control assemblies, each temperature control assembly comprising: a respective thermal interface material (TIM) layer disposed on the surface of a respective metal fixture configured to align with the shape and size of a battery; a respective thermoelectric junction disposed between the respective metal fixture and a respective heat sink, wherein each respective heat sink is coupled to a respective ducted fan assembly; and a respective relay switch coupled to each respective thermoelectric junction; a positive contact fixture configured to contact a positive electrode of the battery: a negative contact fixture configured to contact a negative electrode of the battery; and a process controller coupled to the relay switches, the process controller configured to control the relay switches to regulate the temperature of the thermoelectric junction plates.

Embodiment 2 is the testing apparatus according to embodiment 1, wherein each of the plurality of temperature control assemblies further comprises a temperature sensor coupled to the respective metal fixture.

Embodiment 3 is the testing apparatus according to embodiment 1 or embodiment 2, wherein the temperature sensor is further coupled to the process controller such that the process controller controls the relay switches based on inputs received from the temperature sensor.

Embodiment 4 is the testing apparatus according to any of embodiments 1 to 3, wherein the thermoelectric junction is a Peltier junction.

Embodiment 5 is the testing apparatus according to any of embodiments 1 to 4, wherein in response to a temperature of the battery being above a predetermined temperature set point, the process controller reverses a direction of current flow to the Peltier junction.

Embodiment 6 is the testing apparatus according to any of embodiments 1 to 5, wherein the thermoelectric junction is controllable to provide heat to, or remove heat from, the battery.

Embodiment 7 is the testing apparatus according to any of embodiments 1 to 6, wherein the battery has a first end and a second end opposite the first end, and wherein the negative contact fixture and the positive contact fixture each contacts the battery proximal to the first end.

Embodiment 8 is the testing apparatus according to any of embodiments 1 to 7, wherein the positive contact fixture comprises a first probe, a second probe, and a third probe, and wherein the first, second, and third probes each contacts a same surface of the positive electrode of the battery.

Embodiment 9 is the testing apparatus according to any of embodiments 1 to 8, wherein the positive contact fixture comprises a single probe.

Embodiment 10 is the testing apparatus according to any of embodiments 1 to 9, wherein the negative contact fixture defines an arcuate profile sized and shaped to engage with a lip of the battery.

Embodiment 11 is the testing apparatus according to any of embodiments 1 to 10, wherein the size and shape of the arcuate profile is less than an arcuate profile defined by the lip of the battery such that the negative contact fixture forms an interference fit with the lip.

Embodiment 12 is the testing apparatus according to any of embodiments 1 to 11, wherein the negative contact fixture comprises an elastically deformable material that elastically deforms to engage with a lip of the battery.

Embodiment 13 is the testing apparatus according to any of embodiments 1 to 12, wherein the negative contact fixture comprises a spring, wherein biasing the spring in a first direction contacts the negative contact fixture with the battery and biasing the spring in a second direction removes contact between the negative test fixture and the battery.

Embodiment 14 is the testing apparatus according to any of embodiments 1 to 13, wherein the negative contact fixture is coupled to a hinge such that (i) rotation of the negative contact fixture about the hinge in a first directions contacts the battery and (ii) rotation of the negative contact fixture about the hinge in a second direction removes contact with the battery.

Embodiment 15 is the testing apparatus according to any of embodiments 1 to 14, wherein the process controller is a pulse width modulation (PWM) controller, and wherein the PWM controller varies a non-zero amount of electrical power supplied to the thermoelectric junctions.

Embodiment 16 is the testing apparatus according to any of embodiments 1 to 15, wherein in response to a temperature of the battery being above a predetermined temperature set point, the process controller increases a fan speed of the respective ducted fan assembly.

Embodiment 17 is the testing apparatus according to any of embodiments 1 to 16, wherein the battery is a cylindrical cell having a top, a bottom opposite the top, and a cylindrical body disposed between the top and the bottom, the plurality of temperature control assemblies further comprising: a first temperature control assembly engaged with the bottom; a second temperature control assembly engaged with a first longitudinal half of the body; and a third temperature control assembly engaged with a second longitudinal half of the body, such that the bottom and the body of the battery are housed within the plurality of temperature control assemblies.

Embodiment 18 is a testing system comprising: a plurality of testing apparatuses, wherein each testing apparatus comprises: a battery; a base; a mounting frame comprising a plurality of supports coupled to the base; a plurality of temperature control assemblies, each temperature control assembly comprising: a respective thermal interface material (TIM) layer disposed on the surface of a respective metal fixture configured to align with the shape and size of the battery; a respective thermoelectric junction disposed between the respective metal fixture and a respective heat sink, wherein each respective heat sink is coupled to a respective ducted fan assembly; and a respective relay switch coupled to each respective thermoelectric junction; a positive contact fixture configured to contact a positive electrode of the battery; a negative contact fixture configured to contact a negative electrode of the battery; and a process controller coupled to the relay switches, the process controller configured to control the relay switches to regulate the temperature of the thermoelectric junction plates; and a computing device coupled to the plurality of testing apparatuses, wherein the computing device receives testing information from each of the plurality of testing apparatuses.

Embodiment 19 is the testing system according to embodiment 18, wherein at least one of the thermoelectric junctions is a Peltier junction.

Embodiment 20 is a method for testing a battery using a testing apparatus comprising a plurality of temperature control assemblies each comprising a thermal interface material disposed on a metal fixture, a heat sink coupled to a ducted fan and the metal fixture, and a thermoelectric junction disposed between the metal fixture and the heat sink, the method comprising: placing the battery into the testing apparatus, wherein the battery contacts a surface of the thermal interface material of each of the plurality of temperature control assemblies; positioning a positive contact of the testing apparatus in contact with a positive electrode of the battery; positioning a negative contact of the testing apparatus in contact with a negative electrode of the battery located proximal to the positive electrode, wherein the negative contact elastically deforms to a surface of the battery; and controlling, using a process controller coupled to the thermoelectric junction, a temperature of the battery by controlling current flow through the thermoelectric junction.

Embodiment 21 is the method according to embodiment 20 performed on any of embodiments 1 to 19.

The present disclosure describes various features and operations of the disclosed systems. The illustrative implementations described herein are not meant to be limiting. Certain aspects of the disclosed systems can be arranged and combined in a variety of different configurations, all of which are contemplated herein.

Further, unless context suggests otherwise, the features illustrated in each of the above described figures may be used separately or in combination. For example, one or more features and/or functions described with respect to various components of the testing apparatus 100, shown in FIGS. 1A-5, may each be independently combinable with one or more features and/or functions described with respect to various components of the testing apparatus 200, shown in FIGS. 6A-15. Thus, the figures should be generally viewed as component aspects of one or more overall implementations, with the understanding that not all illustrated features are necessary for each implementation.

Additionally, any enumeration of elements, blocks, or steps in this disclosure is for purposes of clarity. Thus, such enumeration should not be interpreted to require or imply that these elements, blocks, or steps adhere to a particular arrangement or are carried out in a particular order.

Further, devices or systems may be used or configured to perform functions presented in the figures. In some instances, components of the devices and/or systems may be configured to perform the functions such that the components are actually configured and structured (with hardware and/or software) to enable such performance. In other examples, components of the devices and/or systems may be arranged to be adapted to, capable of, or suited for performing the functions, such as when operated in a specific manner.

The arrangements described herein are for purposes of example only. As such, those skilled in the art will appreciate that other arrangements and other elements (e.g., machines, interfaces, operations, orders, and groupings of operations, etc.) can be used instead, and some elements may be omitted altogether according to the desired results. Further, many of the elements that are described are functional entities that may be implemented as discrete or distributed components or in conjunction with other components, in any suitable combination and location.

While various aspects and implementations have been disclosed herein, other aspects and implementations will be apparent to those skilled in the art. The various aspects and implementations disclosed herein are for purposes of illustration and are not intended to be limiting. Also, the terminology used herein is for the purpose of describing particular implementations only and is not intended to be limiting.

1. A testing apparatus comprising:
a base;
a mounting frame comprising a plurality of supports coupled to the base;
a plurality of temperature control assemblies, each temperature control assembly comprising:
a respective thermal interface material (TIM) layer disposed on the surface of a respective metal fixture configured to align with the shape and size of a battery;
a respective thermoelectric junction disposed between the respective metal fixture and a respective heat sink, wherein each respective heat sink is coupled to a respective ducted fan assembly; and
a respective relay switch coupled to each respective thermoelectric junction;
a positive contact fixture configured to contact a positive electrode of the battery;
a negative contact fixture configured to contact a negative electrode of the battery; and
a process controller coupled to the relay switches, the process controller configured to control the relay switches to regulate the temperature of the thermoelectric junction plates.

2. The testing apparatus of claim 1, wherein each of the plurality of temperature control assemblies further comprises a temperature sensor coupled to the respective metal fixture.

3. The testing apparatus of claim 2, wherein the temperature sensor is further coupled to the process controller such that the process controller controls the relay switches based on inputs received from the temperature sensor.

4. The testing apparatus of claim 1, wherein the thermoelectric junction is a Peltier junction.

5. The testing apparatus of claim 4, wherein in response to a temperature of the battery being above a predetermined temperature set point, the process controller reverses a direction of current flow to the Peltier junction.

6. The testing apparatus of claim 1, wherein the thermoelectric junction is controllable to provide heat to, or remove heat from, the battery.

7. The testing apparatus of claim 1, wherein the battery has a first end and a second end opposite the first end, and wherein the negative contact fixture and the positive contact fixture each contacts the battery proximal to the first end.

8. The testing apparatus of claim 1, wherein the positive contact fixture comprises a first probe, a second probe, and a third probe, and wherein the first, second, and third probes each contacts a same surface of the positive electrode of the battery.

9. The testing apparatus of claim 1, wherein the positive contact fixture comprises a single probe.

10. The testing apparatus of claim 1, wherein the negative contact fixture defines an arcuate profile sized and shaped to engage with a lip of the battery.

11. The testing apparatus of claim 10, wherein the size and shape of the arcuate profile is less than an arcuate profile defined by the lip of the battery such that the negative contact fixture forms an interference fit with the lip.

12. The testing apparatus of claim 1, wherein the negative contact fixture comprises an elastically deformable material that elastically deforms to engage with a lip of the battery.

13. The testing apparatus of claim 1, wherein the negative contact fixture comprises a spring, wherein biasing the spring in a first direction contacts the negative contact fixture with the battery and biasing the spring in a second direction removes contact between the negative test fixture and the battery.

14. The testing apparatus of claim 1, wherein the negative contact fixture is coupled to a hinge such that (i) rotation of the negative contact fixture about the hinge in a first directions contacts the battery and (ii) rotation of the negative contact fixture about the hinge in a second direction removes contact with the battery.

15. The testing apparatus of claim 1, wherein the process controller is a pulse width modulation (PWM) controller, and wherein the PWM controller varies a non-zero amount of electrical power supplied to the thermoelectric junctions.

16. The testing apparatus of claim 1, wherein in response to a temperature of the battery being above a predetermined temperature set point, the process controller increases a fan speed of the respective ducted fan assembly.

17. The testing apparatus of claim 1, wherein the battery is a cylindrical cell having a top, a bottom opposite the top, and a cylindrical body disposed between the top and the bottom, the plurality of temperature control assemblies further comprising:
a first temperature control assembly engaged with the bottom;
a second temperature control assembly engaged with a first longitudinal half of the body; and
a third temperature control assembly engaged with a second longitudinal half of the body, such that the bottom and the body of the battery are housed within the plurality of temperature control assemblies.

18. A testing system comprising:
a plurality of testing apparatuses, wherein each testing apparatus comprises:
a battery;
a base;
a mounting frame comprising a plurality of supports coupled to the base;
a plurality of temperature control assemblies, each temperature control assembly comprising:
a respective thermal interface material (TIM) layer disposed on the surface of a respective metal fixture configured to align with the shape and size of the battery;
a respective thermoelectric junction disposed between the respective metal fixture and a respective heat sink, wherein each respective heat sink is coupled to a respective ducted fan assembly; and
a respective relay switch coupled to each respective thermoelectric junction;
a positive contact fixture configured to contact a positive electrode of the battery;
a negative contact fixture configured to contact a negative electrode of the battery; and
a process controller coupled to the relay switches, the process controller configured to control the relay switches to regulate the temperature of the thermoelectric junction plates; and
a computing device coupled to the plurality of testing apparatuses, wherein the computing device receives testing information from each of the plurality of testing apparatuses.

19. The testing system of claim 18, wherein at least one of the thermoelectric junctions is a Peltier junction.

20. A method for testing a battery using a testing apparatus comprising a plurality of temperature control assemblies each comprising a thermal interface material disposed on a metal fixture, a heat sink coupled to a ducted fan and the metal fixture, and a thermoelectric junction disposed between the metal fixture and the heat sink, the method comprising:
placing the battery into the testing apparatus, wherein the battery contacts a surface of the thermal interface material of each of the plurality of temperature control assemblies;
positioning a positive contact of the testing apparatus in contact with a positive electrode of the battery;
positioning a negative contact of the testing apparatus in contact with a negative electrode of the battery located proximal to the positive electrode, wherein the negative contact elastically deforms to a surface of the battery; and
controlling, using a process controller coupled to the thermoelectric junction, a temperature of the battery by controlling current flow through the thermoelectric junction.
